(19) United States
(12) Patent Application Publication
(10) Pub. No.: US 2025/0351624 A1
(43) Pub. Date: Nov. 13, 2025

(54) LIGHT EMITTING ELEMENT AND DISPLAY DEVICE INCLUDING THE SAME

(71) Applicant: Samsung Display Co., LTD., Yongin-si (KR)

(72) Inventors: Hyun Min CHO, Yongin-si (KR); Young Chul SIM, Yongin-si (KR); Kwan Jae LEE, Yongin-si (KR)

(73) Assignee: Samsung Display Co., LTD., Yongin-si (KR)

(21) Appl. No.: 19/189,668

(22) Filed: Apr. 25, 2025

(30) Foreign Application Priority Data
May 9, 2024 (KR) 10-2024-0061037

(51) Int. Cl. H10H 20/821; H10H 20/812; H10H 20/84; H10H 29/01; H10H 29/49

(52) U.S. Cl. CPC H10H 20/821; H10H 20/812; H10H 20/84; H10H 29/011; H10H 29/034; H10H 29/49

(57) ABSTRACT

A light emitting element includes a first semiconductor layer doped with an n-type dopant, a second semiconductor layer disposed on the first semiconductor layer and doped with a p-type dopant, an active layer disposed between the first semiconductor layer and the second semiconductor layer, an electrode layer disposed on the second semiconductor layer, and an insulating film surrounding at least a side surface of the active layer. The first semiconductor layer has a diameter in a range of about 0.5 μm to about 10 μm, and the light emitting element has an external quantum efficiency greater than or equal to about 23%.

### CROSS-REFERENCE TO RELATED APPLICATION(S)

This application claims priority to and benefits of Korean Patent Application No. 10-2024-0061037 under 35 U.S.C. 119, filed on May 9, 2024, in the Korean Intellectual Property Office (KIPO), the entire contents of which are incorporated herein by reference.

### BACKGROUND

### 1. Technical Field

The disclosure relates to a light emitting element and a display device including the same.

### 2. Description of the Related Art

The importance of display devices has steadily increased with the development of multimedia technology. Along with this trend, various types of display devices such as an organic light emitting display (OLED), a liquid crystal display (LCD) and the like have been used.

As a device for displaying an image of a display device, there is a self-light emitting display device including a light emitting element. The self-light emitting display device includes an organic light emitting display device using an organic material as a light emitting material for a light emitting element, an inorganic light emitting display device using an inorganic material as a light emitting material, or the like.

### SUMMARY

Aspects of the disclosure provide a light emitting element having improved luminous efficiency, and a display device including the same.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment of the disclosure, a light emitting element may include a first semiconductor layer doped with an n-type dopant, a second semiconductor layer disposed on the first semiconductor layer and doped with a p-type dopant, an active layer disposed between the first semiconductor layer and the second semiconductor layer, an electrode layer disposed on the second semiconductor layer, and an insulating film surrounding at least a side surface of the active layer. The first semiconductor layer may have a diameter in a range of about 0.5 μm to about 10 μm, and the light emitting element may have an external quantum efficiency greater than or equal to about 23%.

In an embodiment, the first semiconductor layer may have the diameter in a range of about 0.5 μm to about 1 μm, and the light emitting element may have the external quantum efficiency in a range of about 23% to about 23.3%.

In an embodiment, the first semiconductor layer may have the diameter in a range of about 1 μm to about 3 μm, and the light emitting element may have the external quantum efficiency in a range of about 23.3% to about 24.2%.

In an embodiment, the first semiconductor layer may have the diameter in a range of about 3 μm to about 5 μm, and the light emitting element may have the external quantum efficiency in a range of about 24.2% to about 25%.

In an embodiment, the first semiconductor layer may have the diameter in a range of about 5 μm to about 10 μm, and the light emitting element may have the external quantum efficiency in a range of about 25% to about 26%.

In an embodiment, the insulating film may include a first insulating film covering side surfaces of the first semiconductor layer, the second semiconductor layer, and the side surface of the active layer, and a second insulating film surrounding the first insulating film, and a thickness of the second insulating film may be greater than a thickness of the first insulating film in a radial direction of the active layer.

In an embodiment, the first insulating film may include a first layer, a second layer surrounding the first layer, and a third layer surrounding the second layer, the first layer and the third layer may include a same material, and a thickness of the first layer may be greater than a thickness of the second layer and a thickness of the third layer in the radial direction.

In an embodiment, the first layer and the third layer may include zirconium oxide (ZrO₂), and the second layer may include aluminum oxide (Al₂O₃) or hafnium oxide (HfO₂).

In an embodiment, the thickness of the first layer may be about 2 nm, and each of the thickness of the second layer and the thickness of the third layer may be about 1 nm.

In an embodiment, the second insulating film may include a fourth layer and a fifth layer surrounding the fourth layer, and a thickness of the fifth layer may be greater than a thickness of the fourth layer in the radial direction.

In an embodiment, each of the fourth layer and the fifth layer may include one of silicon oxide (SiOₓ), silicon nitride (SiNₓ), silicon oxynitride (SiOₓN_{y}), aluminum nitride (AlNₓ), aluminum oxide (Al₂O₃), zirconium oxide (ZrOₓ), hafnium oxide (HfOₓ), and titanium oxide (TiOₓ), x may be a rational number, and y may be another rational number.

In an embodiment, the thickness of the fourth layer may be greater than or equal to about 10 nm, and the thickness of the fifth layer may be in a range of about 40 nm to about 100 nm.

In an embodiment, the active layer may include a plurality of well layers and a plurality of barrier layers alternately stacked with each other, and each of the plurality of well layers may include indium (In) and include a region where the indium is locally aggregated.

In an embodiment, each of the plurality of well layers of the active layer may have a non-uniform density of an indium per unit area along a longitudinal direction of the active layer.

In an embodiment, each of the plurality of well layers of the active layer may have a non-uniform density of an indium per unit area along a radial direction of the active layer.

According to an embodiment of the disclosure, a display device may include a first electrode and a second electrode spaced apart from each other above a substrate, and a light emitting element electrically connected to each of the first electrode and the second electrode, and having a shape extending in a direction. The light emitting element may include a first semiconductor layer doped with an n-type dopant, a second semiconductor layer disposed on the first semiconductor layer and doped with a p-type dopant, an active layer disposed between the first semiconductor layer and the second semiconductor layer, an electrode layer disposed on the second semiconductor layer, and an insulating film surrounding at least a side surface of the active layer. The first semiconductor layer may have a diameter in a range of about 0.5 μm to about 10 μm, and the light emitting element may have an external quantum efficiency greater than or equal to about 23%.

In an embodiment, the insulating film of the light emitting element may include a first layer covering side surfaces of the first semiconductor layer, the second semiconductor layer, and the side surface of the active layer, a second layer surrounding the first layer, a third layer surrounding the second layer, a fourth layer covering the third layer, and a fifth layer surrounding the fourth layer, the first layer and the third layer may include a same material, a thickness of the first layer may be greater than a thickness of the second layer and a thickness of the third layer in a radial direction of the active layer, and a thickness of the fifth layer may be greater than a thickness of the fourth layer in the radial direction.

In an embodiment, the first layer and the third layer may include zirconium oxide (ZrO₂), the second layer may include aluminum oxide (Al₂O₃) or hafnium oxide (HfO₂), and each of the fourth layer and the fifth layer may include one of silicon oxide (SiOₓ), silicon nitride (SiNₓ), silicon oxynitride (SiOₓN_{y}), aluminum nitride (AlNₓ), aluminum oxide (Al₂O₃), zirconium oxide (ZrOₓ), hafnium oxide (HfOₓ), and titanium oxide (TiOₓ). x may be a rational number, and y may be another rational number.

In an embodiment, the thickness of the first layer may be about 2 nm, each of the thickness of the second layer and the thickness of the third layer may be about 1 nm, the thickness of the fourth layer may be greater than or equal to about 10 nm, and the thickness of the fifth layer may be in a range of about 40 nm to about 100 nm.

In an embodiment, the active layer of the light emitting element may include a plurality of well layers and a plurality of barrier layers alternately stacked with each other, each of the plurality of well layers may include indium (In) and include a region where the indium is locally aggregated, and each of the plurality of well layers of the active layer may have a non-uniform density of an indium per unit area along a longitudinal direction and a radial direction of the active layer.

A light emitting element according to one embodiment may have high external quantum efficiency compared to its small diameter by adjusting the characteristics of an insulating film and an active layer surrounding semiconductor layers.

A display device according to one embodiment may include a light emitting element and have high luminous efficiency.

However, effects of the disclosure are not limited to those exemplified above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic diagram of a light emitting element according to one embodiment;

FIG. 2 is a schematic cross-sectional view of the light emitting element of FIG. 1;

FIG. 3 is a schematic cross-sectional view showing in detail an active layer of a light emitting element according to one embodiment;

FIG. 4 is a schematic cross-sectional view showing in detail a well layer included in an active layer of a light emitting element according to one embodiment;

FIG. 5 is a flowchart showing a method of manufacturing a light emitting element according to one embodiment;

FIGS. 6 to 8 are schematic cross-sectional views partially showing a manufacturing process of a light emitting element according to one embodiment;

FIG. 9 is a graph showing a variation of a process temperature over time when forming a multi-quantum well structure during a manufacturing process of a light-emitting element according to one embodiment;

FIGS. 10 and 11 are photographs showing an indium-aggregated region of an active material layer according to one embodiment;

FIGS. 12 to 21 are schematic cross-sectional views partially showing a manufacturing process of a light emitting element according to one embodiment;

FIG. 22 is a schematic cross-sectional view of a display device according to one embodiment;

FIGS. 23 and 24 are schematic cross-sectional views of a display device according to another embodiment; and

FIGS. 25 to 30 are schematic diagrams showing electronic devices including a display device according to one embodiment.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be more thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

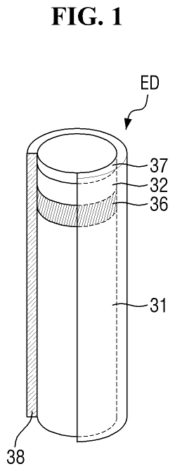

FIG. 1 is a schematic diagram of a light emitting element according to one embodiment.

Referring to FIG. 1, a light emitting element ED may be a light emitting diode. For example, the light emitting element ED may be an inorganic light emitting diode that has a nanometer or micrometer size, and is made of an inorganic material. The light emitting element ED may be disposed between two opposing electrodes and may emit light by an electrical signal applied from the electrodes.

The light emitting element ED according to one embodiment may have a shape extending in a direction. The light emitting element ED may have a shape of a cylinder, a rod, a wire, a tube, or the like. However, the shape of the light emitting element ED is not limited thereto, and the light emitting element ED may have a polygonal prism shape such as a regular cube, a rectangular parallelepiped and a hexagonal prism, or may have various shapes such as a shape extending in a direction and having an outer surface partially inclined.

The light emitting element ED may include a semiconductor layer doped with a conductivity type (e.g., p-type or n-type) dopant. The semiconductor layer may emit light of a specific wavelength band by receiving an electrical signal applied from an external power source. The light emitting element ED may include a first semiconductor layer 31, a second semiconductor layer 32, an active layer 36, an electrode layer 37, and an insulating film 38. The first semiconductor layer 31 may be an n-type semiconductor. The first semiconductor layer 31 may include a semiconductor material having a chemical formula of AlₓGa_{y}In_{1-x-y}N (0≤x≤1, 0≤y≤1, 0≤x+y≤1). For example, the first semiconductor layer 31 may include at least one of AlGaInN, GaN, AlGaN, InGaN, AlN, and InN doped with an n-type dopant. The n-type dopant doped into the first semiconductor layer 31 may be Si, Ge, Sn, Se, or the like.

The second semiconductor layer 32 may be disposed on the first semiconductor layer 31 with the active layer 36 interposed between the second semiconductor layer 32 and the first semiconductor layer 31. The second semiconductor layer 32 may be a p-type semiconductor, and the second semiconductor layer 32 may include a semiconductor material having a chemical formula of AlₓGa_{y}In_{1-x-y}N (0≤x≤1, 0≤y≤1, 0≤x+y≤1). For example, the second semiconductor layer 32 may include at least one of AlGaInN, GaN, AlGaN, InGaN, AlN, and InN doped with a p-type dopant. The p-type dopant doped into the second semiconductor layer 32 may be Mg, Zn, Ca, Ba, or the like.

Although it is illustrated in the drawing that the first semiconductor layer 31 and the second semiconductor layer 32 are configured as one layer, the disclosure is not limited thereto. Depending on the material of the active layer 36, the first semiconductor layer 31 and the second semiconductor layer 32 may further include another layer, such as a cladding layer or a tensile strain barrier reducing (TSBR) layer. For example, the light emitting element ED may further include another semiconductor layer disposed between the first semiconductor layer 31 and the active layer 36, or between the second semiconductor layer 32 and the active layer 36. The semiconductor layer disposed between the first semiconductor layer 31 and the active layer 36 may include at least one of AlGaInN, GaN, AlGaN, InGaN, AlN, and InN doped with an n-type dopant, and the semiconductor layer disposed between the second semiconductor layer 32 and the active layer 36 may include at least one of AlGaInN, GaN, AlGaN, InGaN, AlN, and InN doped with a p-type dopant.

The active layer 36 may be disposed between the first semiconductor layer 31 and the second semiconductor layer 32. The active layer 36 may include a material having a single or multiple quantum well structure. In case that the active layer 36 includes a material having a multiple quantum well structure, multiple barrier layers and well layers may be alternately stacked each other. The active layer 36 may emit light by coupling of electron-hole pairs according to an electrical signal applied through the first semiconductor layer 31 and the second semiconductor layer 32. The active layer 36 may include a material such as AlGaN, AlGaInN, or InGaN. For example, in case that the active layer 36 has a multiple quantum well structure in which barrier layers and well layers are alternately stacked each other, the barrier layer may include a material such as GaN or AlInN, and the well layer may include a material such as AlGaN or AlInGaN.

The active layer 36 may have a structure in which semiconductor materials having a large band gap energy and semiconductor materials having a small band gap energy are alternately stacked each other, and may include group III to V semiconductor materials depending on the wavelength band of the emitted light. The light emitted by the active layer 36 is not limited to light of a blue wavelength band, but the active layer 36 may emit light of a red or green wavelength band in another embodiment.

The electrode layer 37 may be an ohmic connection electrode. However, the disclosure is not limited thereto, and the electrode layer 37 may be a Schottky connection electrode. The light emitting element ED may include at least one electrode layer 37. The light emitting element ED may include one or more electrode layers 37, but the disclosure is not limited thereto, and the electrode layer 37 may be omitted.

In case that the light emitting element ED is electrically connected to an electrode or a connection electrode, the electrode layer 37 may reduce the resistance between the light emitting element ED and the electrode or connection electrode. The electrode layer 37 may include a conductive metal. For example, the electrode layer 37 may include at least one of aluminum (Al), titanium (Ti), indium (In), gold (Au), silver (Ag), ITO, IZO, and ITZO.

The insulating film 38 may surround the outer surfaces of the semiconductor layers and electrode layers described above. For example, the insulating film 38 may surround at least the outer surface of the active layer 36, and may expose ends of the light emitting element ED in a longitudinal direction. In an embodiment, in a cross-sectional view, the insulating film 38 may have a top surface rounded in a region adjacent to at least one end of the light emitting element ED. As will be described below, the insulating film 38 may have a structure in which one or more layers of insulating materials are stacked each other.

The insulating film 38 may perform a function of protecting the semiconductor layers and the electrode layer of the light emitting element ED. The insulating film 38 may prevent an electrical short circuit that may occur at the active layer 36 in case that an electrode to which an electrical signal is transmitted is in direct contact with the light emitting element ED. The insulating film 38 may also prevent a decrease in luminous efficiency of the light emitting element ED.

In some embodiments, the insulating film 38 may have an outer surface which is surface-treated. The light emitting elements ED may be sprayed onto the electrode while being dispersed in an ink. The surface of the insulating film 38 may be treated to have a hydrophobic property or hydrophilic property in order to keep the light emitting elements ED in the dispersed state without being aggregated with other adjacent light emitting elements ED in the ink.

The light emitting element ED according to one embodiment may have relatively small diameter and size, and as its size is small, the external quantum efficiency (EQE) of the light emitting element ED may be lower than the external quantum efficiency of other inorganic light emitting diodes. Further, surface defects that may be formed in the semiconductor layers 31 and 32 and the active layer 36 during the manufacturing process of the light emitting element ED may also be a factor that lowers the external quantum efficiency.

As will be described below, the light emitting element ED may be grown on a substrate through epitaxial growth. In some embodiments, the semiconductor layers 31 and 32, the active layer 36 and the electrode layer 37 of the light emitting element ED may be formed as semiconductor material layers respectively made of a same materials, and the semiconductor layers 31 and 32, the active layer 36 and the electrode layer 37 stacked sequentially may be etched along a mask pattern in a stacked direction, for example, in a vertical direction of a growth substrate. In the etching process of the semiconductor material layers, defects may occur on the etched and exposed surfaces of the semiconductor layers 31 and 32 and the active layer 36. In a small-sized light emitting element ED, the defects formed in the semiconductor layers 31 and 32 and the active layer 36 may have a significant impact on the external quantum efficiency of the light emitting element ED.

The defects formed in the semiconductor layers 31 and 32 and the active layer 36 of the light emitting element ED may affect the electrical and optical characteristics of the light emitting element ED, and, as a result, may also affect the luminous efficiency of a display device 10. If the defects formed on the surfaces of the semiconductor layers 31 and 32 and the active layer 36 can be reduced or controlled, the electrical and optical characteristics of the light emitting element ED may be improved, and the luminous efficiency of the display device 10 may also be improved.

In the light emitting element ED according to one embodiment, its luminous efficiency may be increased or the defects that may be formed on the surfaces of the semiconductor layers 31 and 32 and the active layer 36 may be reduced or minimized through the structure of the insulating film 38 surrounding the surfaces of the semiconductor layers 31 and 32 and the active layer 36 and through the formation process of the insulating film 38 or the manufacturing process by the epitaxial growth method. Accordingly, the light emitting element ED according to one embodiment may have an external quantum efficiency (EQE) of greater than or equal to about 23% even in case that the diameter of the light emitting element ED is small, for example, even in case that the semiconductor layers 31 and 32 of the light emitting element ED have a diameter less than or equal to about 10 μm.

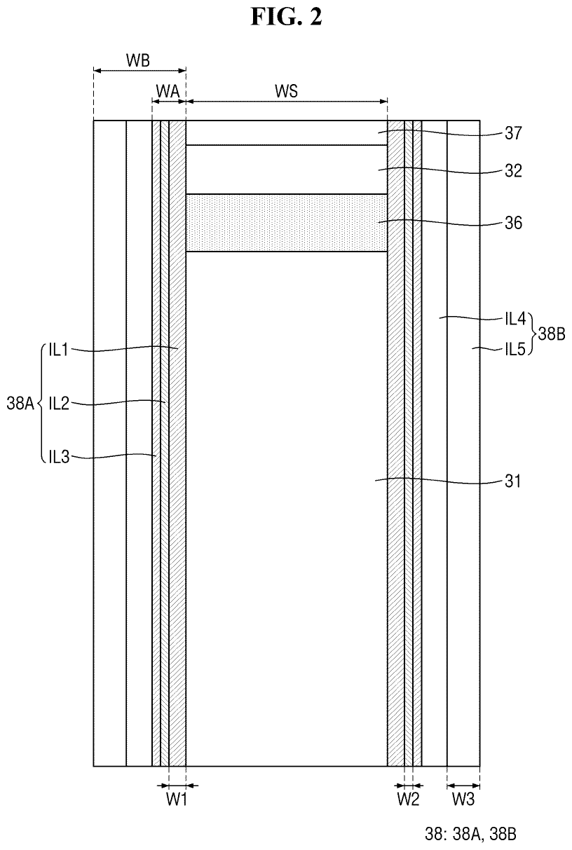

FIG. 2 is a schematic cross-sectional view of the light emitting element of FIG. 1.

Referring to FIG. 2 in addition to FIG. 1, in the light emitting element ED according to one embodiment, the insulating film 38 surrounding the semiconductor layers 31 and 32 and the active layer 36 may include at least insulating layer. For example, the insulating film 38 may include a first insulating film 38A in direct contact with the side surfaces of the semiconductor layers 31 and 32 and the active layer 36, and a second insulating film 38B surrounding the outer surface of the first insulating film 38A. The first insulating film 38A may serve to reduce the surface defects of the light emitting element ED as well as the factors that reduce the external quantum efficiency (EQE) of the light emitting element ED in the insulating film 38. The second insulating film 38B may prevent the light emitting element ED from being damaged during a manufacturing process of a display device in case that the light emitting element ED is applied to the display device.

According to one embodiment, the first insulating film 38A may include a first layer IL1, a second layer IL2, and a third layer IL3. Each of the first layer IL1 and the third layer IL3 may include zirconium oxide (ZrO₂), and the second layer IL2 may include aluminum oxide (Al₂O₃) or hafnium oxide (HfO₂). The first insulating film 38A may have a stacked structure of ZrO₂/Al₂O₃ or HfO₂/ZrO₂, and may act as a barrier to prevent the material of the second insulating film 38B from permeating into the defects formed on the surfaces of the semiconductor layers 31 and 32 and the active layer 36 while reducing the defects.

In an embodiment, the first insulating film 38A may include the third layer IL3 covering the second layer IL2 and thus minimize the thickness of the second layer IL2. In a region where the first layer IL1 and the second layer IL2 are in contact with each other, a metal component of the second layer IL2 may diffuse into the first layer IL1 to form a defect. However, as the third layer IL3 including a same material as the first layer IL1 covers the second layer IL2 while minimizing the thickness of the second layer IL2, the aforementioned defect may be reduced. In an embodiment, the first layer IL1 may have a thickness W 1 of about 2 nm, and each of the second layer IL2 and the third layer IL3 may have a thickness W 2 of about 1 nm in a radial direction of the light emitting element ED. Accordingly, the first insulating film 38A may have a total thickness WA in a range of about 4 nm to about 5 nm.

The second insulating film 38B may include a fourth layer IL4 surrounding the first insulating film 38A, and a fifth layer IL5 surrounding the fourth layer IL4. The fifth layer IL5 may be an outermost insulating layer of the insulating film 38 and may prevent the light emitting element ED from being damaged during the manufacturing process of the display device including the light emitting element ED. The fourth layer IL4 may prevent a metal component included in the fifth layer IL5 from diffusing into the first insulating film 38A to form a defect when the fifth layer IL5 is formed. In an embodiment, each of the fourth layer IL4 and the fifth layer IL5 of the second insulating film 38B may include at least one material having insulating properties such as silicon oxide (SiOₓ), silicon nitride (SiNₓ), silicon oxynitride (SiOₓN_{y}), aluminum nitride (AlNₓ), aluminum oxide (Al₂O₃), zirconium oxide (ZrOₓ), hafnium oxide (HfOₓ), or titanium oxide (TiOₓ). For example, the fourth layer IL4 may include silicon oxide (SiOₓ), and the fifth layer IL5 may include aluminum oxide (Al₂O₃). However, the disclosure is not limited thereto.

In an embodiment, the fourth layer IL4 of the second insulating film 38B may have a thickness greater than or equal to about 10 nm, and the fifth layer IL5 may have a thickness W 3 in a range of about 40 nm to about 100 nm in a radial direction of the light emitting element ED. The fourth layer IL4 may have a thickness sufficient to prevent the metal component of the fifth layer IL5 from diffusing into the first insulating film 38A. In an embodiment, the fifth layer IL5 may have a thickness sufficient to prevent damage to the light emitting element ED during the manufacturing process of the display device. In an embodiment, the semiconductor layers 31 and 32 of the light emitting element ED may have a diameter WS in a range of about 0.5 μm to about 10 μm, the second insulating film 38B may have a thickness WB of at least 50 nm, and the insulating film 38 may have a thickness of at least 54 nm. If the insulating film 38 of the light emitting element ED has a thickness less than or equal to 54 nm, the effectiveness of protecting the light emitting element ED and improving optical properties may be reduced. If the insulating film 38 of the light emitting element ED is too thick, the diameter of the light emitting element ED may increase excessively, which makes it difficult to apply the light emitting element ED to the display device 10. The external quantum efficiency and the electrical characteristics of the light emitting element ED may be further improved as the thickness of the insulating film 38 increases. In another embodiment, the light emitting element ED may have one or more insulating films 38 stacked on top of each other.

The diameter WS shown in the drawing may not necessarily be limited to the diameter of the first semiconductor layer 31 or the second semiconductor layer 32 in the specification. In an embodiment, in case that the semiconductor layers 31 and 32, the active layer 36, and the electrode layer 37 have a same diameter, the diameter WS shown in the drawing may be a diameter of the semiconductor layers 31 and 32, the active layer 36, or the electrode layer 37. In another embodiment, the diameter WS shown in the drawing may be a diameter of a semiconductor core portion surrounded by the insulating film 38 in the light emitting element ED.

The light emitting element ED according to one embodiment may have improved optical properties, high external quantum efficiency, and low leakage current below a threshold voltage. In one embodiment, the diameter of the semiconductor layers 31 and 32 of the light emitting element ED may be in a range of about 0.5 μm to about 10 μm, and the external quantum efficiency of the light emitting element ED may be greater than or equal to about 23%.

In an embodiment, the insulating film 38 of the light emitting element ED may be formed through a sol-gel process, and may reduce or minimize the defects that may be formed on the surfaces of the semiconductor layers 31 and 32 and the active layer 36.

M any defects, such as dangling bonds, defects due to strain relaxation, or damage due to an etching process, may occur on the surfaces of the semiconductor material layers exposed during the etching process of the semiconductor material layers. Defects in the semiconductor layers of the light emitting element ED may be a factor that lowers the external quantum efficiency of the light emitting element ED. The insulating film 38 surrounding the semiconductor layers may reduce damage caused by the defects or cure the defects, thus minimizing the deterioration of the external quantum efficiency. The process of forming the insulating film 38 may be a chemical process involving a thermal process and a plasma process, and may be performed through chemical vapor deposition (CVD) or atomic layer deposition (ALD). However, with the progress of the aforementioned processes in the process of forming the insulating film 38, the surface of the semiconductor layer may be exposed to an environment vulnerable to defects, and the defect may be reduced due to the formation of the insulating film 38.

In the light emitting element ED according to one embodiment, the insulating film 38 may be formed through a sol-gel process that does not include a thermal process and a plasma process, unlike the chemical vapor deposition (CV D) or atomic layer deposition (ALD). Since the insulating film 38 of the light emitting element ED is formed through the sol-gel process, the insulating film 38 may be formed on and adsorbed to the surfaces of the semiconductor layers 31 and 32 and the active layer 36 without an interatomic bonding reaction, unlike other chemical deposition processes. Accordingly, defects and dangling bonds that can be generated on the surfaces of the semiconductor layers 31 and 32 and the active layer 36 of the light emitting element ED may be minimized. A detailed description thereof will be given below.

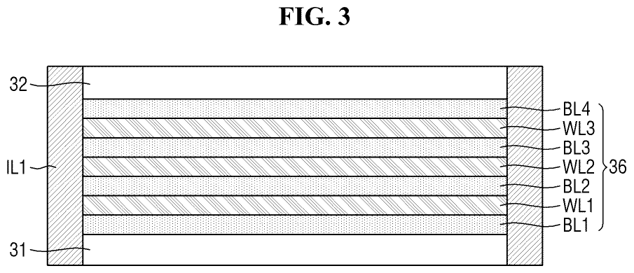

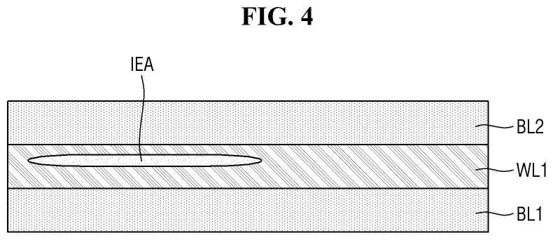

FIG. 3 is a schematic cross-sectional view showing in detail an active layer of a light emitting element according to one embodiment. FIG. 4 is a schematic cross-sectional view showing in detail a well layer included in an active layer of a light emitting element according to one embodiment.

Referring to FIGS. 3 and 4, the active layer 36 of the light emitting element ED according to one embodiment may include multiple barrier layers BL1, BL2, BL3 and BL4, and multiple well layers WL1, WL2 and WL3. The well layers WL1, WL2, and WL3 may include a region in which indium (In) is locally aggregated. As described above, the active layer 36 may have a multiple quantum well structure, and may have a structure in which the barrier layers BL1, BL2, BL3, and BL4 and the well layers WL1, WL2, and WL3 are alternately stacked with each other. The drawing schematically illustrates that the four barrier layers BL1, BL2, BL3, BL4 and the three well layers WL1, WL2, and WL3 are alternately arranged, and the semiconductor layers 31 and 32 are respectively in contact with the barrier layers BL1 and BL4. For example, the first barrier layer BL1, the second barrier layer BL2, the third barrier layer BL3, and the fourth barrier layer BL4 may be sequentially stacked, and the first well layer WL1, the second well layer WL2, and the third well layer WL3 may be respectively disposed between adjacent barrier layers BL1, BL2, BL3, and BL4. However, the disclosure is not limited thereto, and the multi-quantum well structure of the active layer 36 may be modified in various ways. For example, the active layer 36 may have a structure in which eight well layers and nine barrier layers are alternately stacked with each other.

In one embodiment, the well layers WL1, WL2, and WL3 of the active layer 36 may include a material such as AlGaN or AlInGaN, and the barrier layers BL1, BL2, BL3, and BL4 may include a material such as GaN or AlInN. The well layers WL1, WL2, and WL3 may further include indium (In) in addition to the GaN-based material. The indium (In) contained in the well layers WL1, WL2, and WL3 may not be uniform throughout the well layers, and may exist in a locally aggregated state. For example, as illustrated in FIG. 4, a region IEA where the indium (In) is locally aggregated may be formed in the first well layer WL1, and the distribution of the indium (In) may not be uniform along a plane (horizontal) direction and a thickness direction. The content of the indium (In) per unit volume in the indium-aggregated region IEA may be greater than the content of the indium (In) per unit volume in other regions.

Electrons injected from the first semiconductor layer 31 may be transferred to the second semiconductor layer 32 through the barrier layers BL1, BL2, BL3, and BL4 and the well layers WL1, WL2, and WL3 in the multi-quantum well structure of the active layer 36. As the electrons move from a conduction band of the multi-quantum well structure to a valence band, light may be emitted. However, some of the electrons may be trapped in defects formed on the side surface of the active layer 36, failing to emit light. With an increase of the number of the electrons caught in the defects formed on the side surface, the external quantum efficiency of the light emitting element ED may decrease.

However, the light emitting element ED according to one embodiment may include the indium-aggregated region IEA formed in the well layers WL1, WL2, and WL3, and the aggregated indium (In) may exert an attractive force on electrons. In case that the electrons move from the active layer 36 to the semiconductor layer, the number of the electrons moving to defects formed on the side surfaces may be reduced due to the aggregated indium (In). The smaller the diameter of the light emitting element ED, the greater the influence of the defects formed on the side surfaces of the semiconductor layers 31 and 32 and the active layer 36. Although the light emitting element ED has a small diameter, as the aggregated indium (In) is included in the well layers WL1, WL2, and WL3 of the active layer 36, the influence of the defects may be reduced. Therefore, the light emitting element ED may have high external quantum efficiency compared to its diameter.

According to one embodiment, the light emitting element ED may include the insulating film 38 in which one or more layers are stacked each other, and may include the indium-aggregated region IEA formed in the multi-quantum well structure of the active layer 36. Thus, the light emitting element ED may have relatively high external quantum efficiency even with a diameter less than or equal to about 10 μm. For example, as shown in Table 1 below, the diameters of the semiconductor layers 31 and 32 and the active layer 36 of the light emitting element ED may be in a range of about 0.5 μm to about 10 μm, and the light emitting element ED may have an external quantum efficiency of greater than or equal to about 23%. The light emitting element ED may have an external quantum efficiency (EQE) in a range of about 23% to about 23.3% in case that the diameter of the semiconductor layers 31 and 32 is in a range of about 0.5 μm to about 1 μm. The light emitting element ED may have an external quantum efficiency (EQE) greater than or equal to about 24.2% in case that the semiconductor layers 31 and 32 have a diameter greater than or equal to about 3 μm, an external quantum efficiency (EQE) greater than or equal to about 25% in case that the semiconductor layers 31 and 32 has a diameter greater than or equal to about 5 μm, and an external quantum efficiency (EQE) greater than or equal to about 26% in case that the semiconductor layers 31 and 32 have a diameter about 10 μm.

TABLE 1

| Diameter (μm) | 0.5 | 1 | 3 | 5 | 10 |
|---|---|---|---|---|---|
| EQE (%) | 23 | 23.3 | 24.2 | 25 | 26 |

The light emitting element ED according to one embodiment may have a structure that reduces surface defects and improves luminous efficiency by forming the insulating film 38 and the active layer 36 through a specific process in the manufacturing process, and thus may have an excellent external quantum efficiency even with its small diameter.

Hereinafter, a method of manufacturing a light emitting element according to one embodiment will be described.

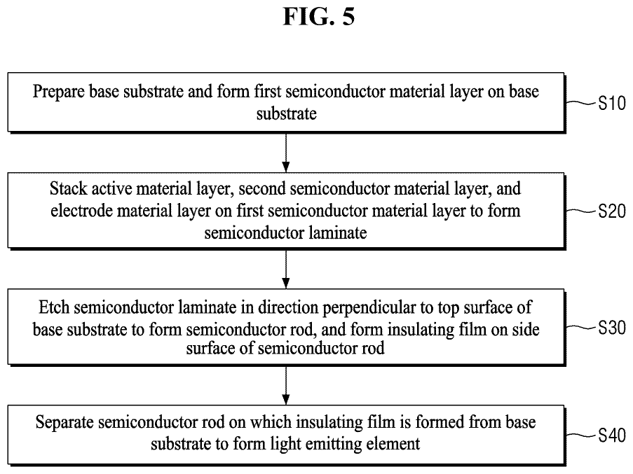

FIG. 5 is a flowchart showing a method of manufacturing a light emitting element according to one embodiment.

Referring to FIG. 5, a method of manufacturing a light emitting element according to one embodiment may include preparing a base substrate and forming a first semiconductor material layer on the base substrate (step S10), stacking an active material layer, a second semiconductor material layer, and an electrode material layer on the first semiconductor material layer to form a semiconductor laminate (step S20), etching the semiconductor laminate in a direction perpendicular to the top surface of the base substrate to form a semiconductor rod, and forming an insulating film on the side surface of the semiconductor rod (step S30), and separating the semiconductor rod on which the insulating film is formed from the base substrate to form the light emitting element (step S40).

A method of manufacturing the light emitting element ED may include forming the semiconductor laminate on the base substrate and etching and separating the semiconductor laminate. In the process of forming the semiconductor laminate, an indium-aggregated region may be formed in the active material layer, and in the process of forming the insulating film, an insulating film composed of multiple layers may be formed to compensate for a side defect of the etched semiconductor rod. Hereinafter, a method of manufacturing a light emitting element will be described in detail with further reference to other drawings.

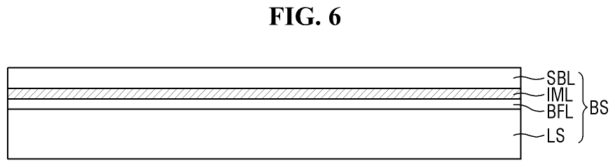

FIGS. 6 to 8 are schematic cross-sectional views partially showing a manufacturing process of a light emitting element according to one embodiment.

Referring to FIG. 6, a base substrate BS on which a semiconductor laminate is to be formed is prepared. The base substrate BS may include a lower substrate LS, a buffer material layer BFL, an intermediate layer IML, and a semiconductor base layer SBL.

The lower substrate LS may include a sapphire substrate (Al₂O₃) and a transparent substrate including glass. However, the disclosure is not limited thereto, and the lower substrate LS may be formed of a conductive material such as GaN, SiC, ZnO, Si, GaP, and GaAs. Although the thickness of the lower substrate LS is not particularly limited, according to an embodiment, the lower substrate LS may have a thickness in a range of about 400 μm to about 1500 μm.

The buffer material layer BFL may reduce a difference in lattice constant between a first semiconductor material layer 310 to be formed on the base substrate BS and the lower substrate LS. In an embodiment, the buffer material layer BFL may include at least one of InAlGaN, GaN, AlGaN, InGaN, AlN, and InN, but the disclosure is not limited thereto.

The intermediate layer IML may be disposed on the buffer material layer BFL to reduce the defect density of a semiconductor layer to be disposed on the base substrate BS. As the intermediate layer IML is formed in the base substrate BS in the manufacturing process of the light emitting element ED, the defect density of semiconductor material layers formed through an epitaxial growth process may be reduced, and the defect density of the manufactured light emitting element ED may also be reduced. Therefore, factors that may lower the external quantum efficiency of the light emitting element ED may be reduced. In one embodiment, the intermediate layer IML may include AlN or SiNₓ.

The semiconductor base layer SBL may provide a seed crystal on which a semiconductor laminate may grow. For example, the semiconductor base layer SBL may include an undoped semiconductor. The semiconductor base layer SBL and the first semiconductor material layer 310 may include substantially a same material as, but semiconductor base layer SBL may be neither n-type doped nor p-type doped, or may have a doping concentration lower than a doping concentration of the first semiconductor material layer 310. For example, the semiconductor base layer SBL may include undoped GaN.

In one embodiment, in the method of manufacturing the light emitting element ED, the intermediate layer IML may be formed in the base substrate BS, and the defect density of the semiconductor base layer SBL may be low. For example, the defect density of the semiconductor base layer SBL including the undoped semiconductor may be less than or equal to about 1.0*10⁸/cm². For example, the defect density of the semiconductor base layer SBL including the undoped semiconductor may be less than or equal to about 6*10⁷/cm².

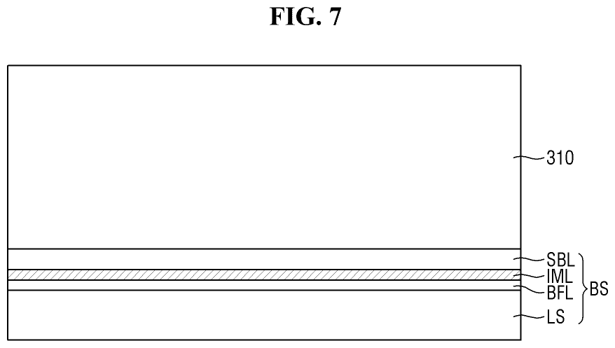

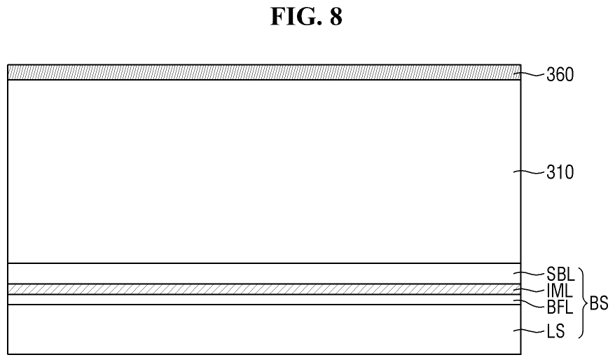

Subsequently, referring to FIGS. 7 and 8, the first semiconductor material layer 310 and an active material layer 360 may be sequentially formed on the semiconductor base layer SBL of the base substrate BS.

The semiconductor material layers may be formed by growing a seed crystal using an epitaxial method. In an embodiment, the semiconductor material layer may be formed using one of electron beam deposition, physical vapor deposition (PVD), chemical vapor deposition (CVD), plasma laser deposition (PLD), dual-type thermal evaporation, sputtering, and metal organic chemical vapor deposition (MOCVD). However, the disclosure is not limited thereto.

A precursor material for forming the semiconductor material layer may be selected to form a target material in a typically selectable range without any limitation. For example, the precursor material may include a metal precursor including an alkyl group such as a methyl group or an ethyl group. For example, in an embodiment in which the first semiconductor layer 31, the second semiconductor layer 32, and the active layer 36 include one of AlGaInN, GaN, AlGaN, InGaN, AlN, and InN, like the light emitting element ED according to one embodiment, the metal precursor may be a compound such as trimethyl gallium (Ga(CH₃)₃), trimethyl aluminum (Al(CH₃)₃), or triethyl phosphate ((C₂H₅)₃PO₄). However, the disclosure is not limited thereto. The semiconductor material layers may be formed through a deposition process using the metal precursor and a non-metal precursor.

According to one embodiment, in the step of forming the active material layer 360 after forming the first semiconductor material layer 310 on the base substrate BS, the deposition process for forming a well layer of a multi-quantum well structure may include a step of changing a temperature. By changing a process temperature when forming the well layer, a region where indium is locally aggregated may be formed in the well layer.

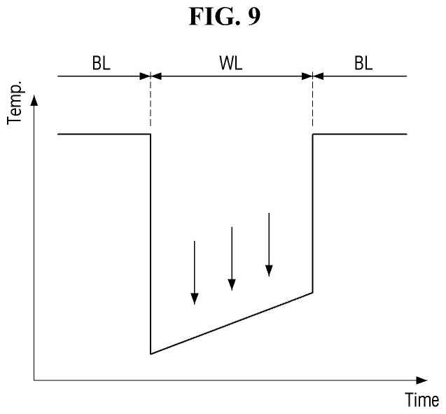

FIG. 9 is a graph showing a variation of a process temperature over time when forming a multi-quantum well structure during a manufacturing process of a light-emitting element according to one embodiment.

Referring to FIG. 9, in the process of forming the active material layer 360, the temperature may be maintained constant over time during the formation of the barrier layer BL. The barrier layer BL may be formed while the injection rate and the temperature of the precursor are kept constant.

In the process of forming the active material layer 360, the formation of the well layer WL may be performed at a lower temperature than the formation of the barrier layer BL. The formation of the well layer WL may include injecting an indium (In) precursor, and may be performed at a relatively low temperature. In one embodiment, the temperature may increase with a lapse of time in the formation of the well layer WL. When the well layer WL is formed on the barrier layer BL, the temperature in a later process may be higher than the temperature in an initial process. As the process temperature varies over time, the distribution of the indium (In) may vary in the thickness direction of the well layer WL. As described above, the distribution of the indium (In) in the well layer WL of the active layer 36 may not be uniform in a horizontal direction and a thickness direction, and the region where the indium (In) is locally aggregated may be formed.

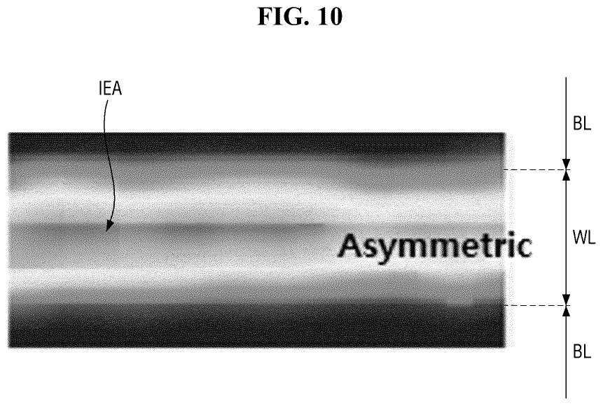

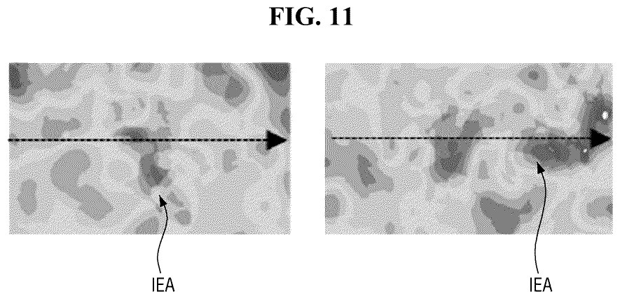

FIGS. 10 and 11 are photographs showing an indium-aggregated region of an active material layer according to one embodiment. FIG. 10 shows the indium-aggregated region of the active material layer in a cross-sectional view taken along the thickness direction, and FIG. 11 shows the indium-aggregated region of the active material layer in a cross-sectional view taken along the plane direction. In FIGS. 10 and 11, a region IEA that is darker than the surrounding region is a region with a high indium (In) content.

Referring to FIGS. 10 and 11, in the method of manufacturing the light emitting element ED according to one embodiment, the distribution of the indium (In) in the active material layer 360 may not be uniform both in the horizontal direction and the thickness direction. The active material layer 360 may include a region IEA where the indium (In) is locally aggregated, and thus may reduce trapping of electrons in surface defects when electrons flow.

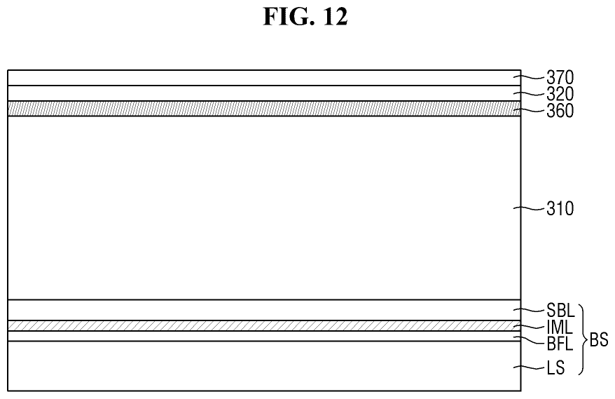

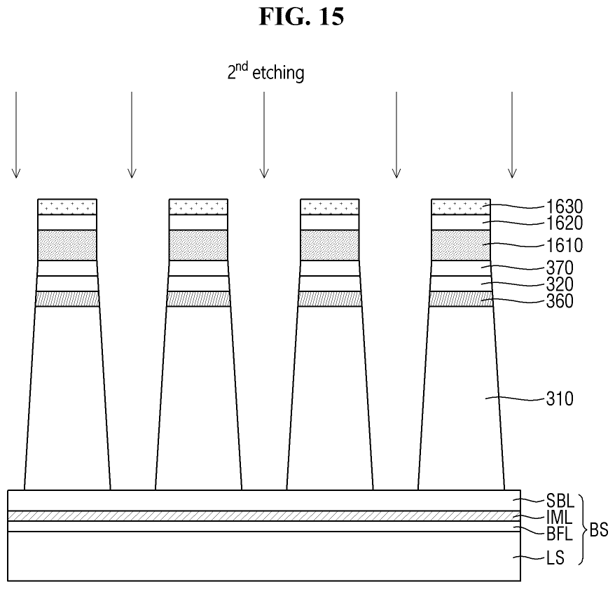

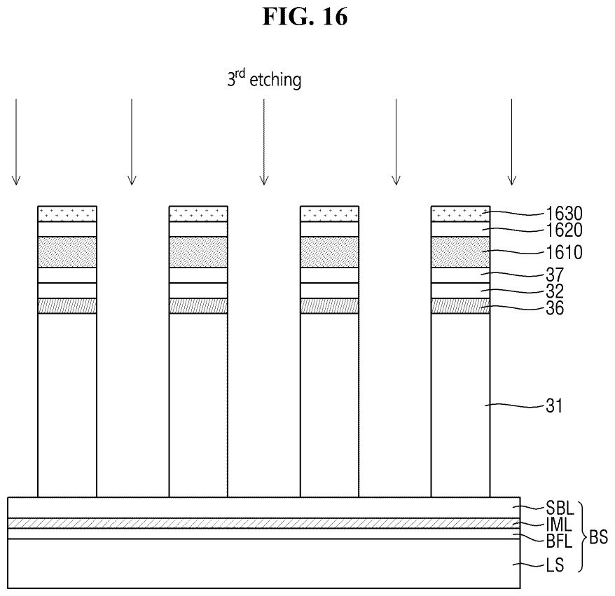

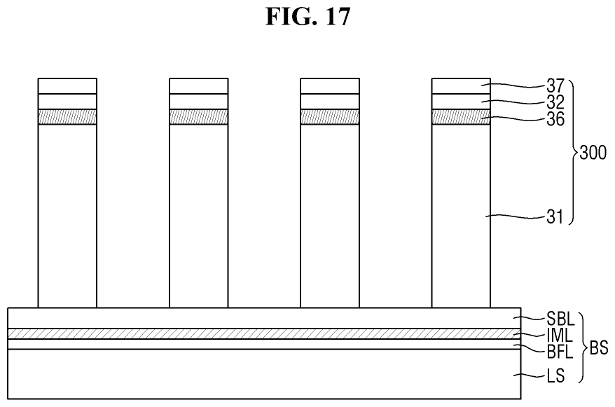

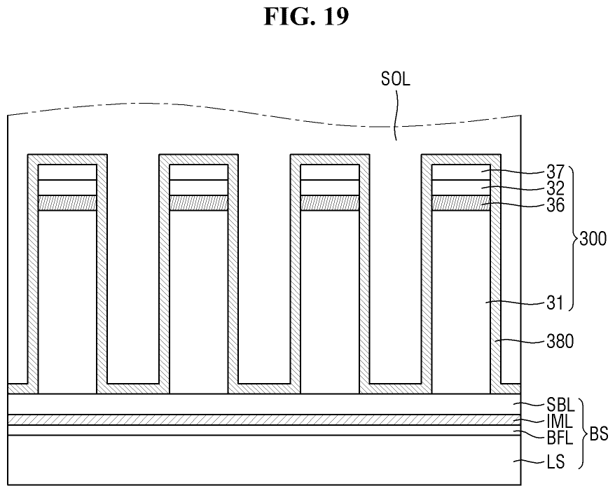

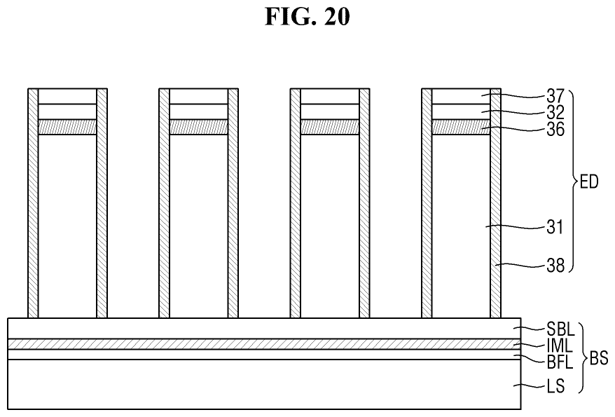

FIGS. 12 to 21 are schematic cross-sectional views partially showing a manufacturing process of a light emitting element according to one embodiment.

Referring to FIG. 12, a second semiconductor material layer 320 and an electrode material layer 370 may be formed on the active material layer 360.

The material layers disposed on the base substrate BS may respectively correspond to the semiconductor layers 31 and 32, the active layer 36, and the electrode layer 37 of the light emitting element ED. For example, the first semiconductor material layer 310 may correspond to the first semiconductor layer 31, and the active material layer 360 and the second semiconductor material layer 320 may correspond to the active layer 36 and the second semiconductor layer 32, respectively. For example, the first semiconductor layer 31 and first semiconductor material layer 310 may include a same material, the second semiconductor layer 32 and the second semiconductor material layer 320 may include a same material, and the active material layer 360 and the active layer 36 may include a same material.

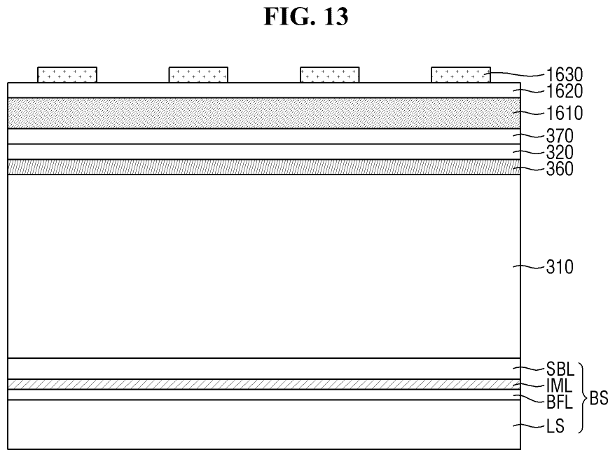

Referring to FIGS. 13 to 17, the semiconductor material layers 310 and 320, the active material layer 360, and the electrode material layer 370 may be etched to form semiconductor rods spaced apart from each other. According to one embodiment, the step of etching the semiconductor material layers 310 and 320, the active material layer 360, and the electrode material layer 370 may include a process (1^{st} etching) of forming a mask layer on the electrode material layer 370, and multiple etching processes (2^{nd} etching and 3^{rd} etching) of etching the semiconductor material layers 310 and 320 and the like along the mask layer.

First, as shown in FIG. 13, multiple mask layers 1610, 1620, and 1630 may be formed on the electrode material layer 370. The mask layers 1610, 1620, and 1630 may include first and second insulating mask layers 1610 and 1620 disposed on the electrode material layer 370, and mask patterns 1630 disposed on the second insulating mask layer 1620. The first insulating mask layer 1610 and the second insulating mask layer 1620 may be etched along the spaces between the mask patterns 1630 spaced apart from each other in a subsequent process. The semiconductor material layers 310, 320, 360, and 370 may be etched along the spaces between the mask patterns 1630 and the insulating mask layers 1610 and 1620. In some embodiments, the mask patterns 1630 may have a same diameter or width. The portion of the semiconductor material layers 310 and 320 that overlaps the portion where the mask pattern 1630 is disposed and is thus not etched may form a semiconductor rod constituting the light emitting element ED. In an embodiment, the diameter of the mask pattern 1630 and the diameter of the light emitting element ED may be substantially the same. As the mask patterns 1630 have a same diameter or width, the light emitting elements ED may also have substantially a same diameter.

The first insulating mask layer 1610 and the second insulating mask layer 1620 may include an insulating material, and the mask pattern 1630 may include a metal material. For example, each of the insulating mask layers 1610 and 1620 may be made of silicon oxide (SiOₓ), silicon nitride (SiNₓ), silicon oxynitride (SiOₓN_{y}), or the like. The mask pattern 1630 may include a metal such as chromium (Cr), but the disclosure is not limited thereto.

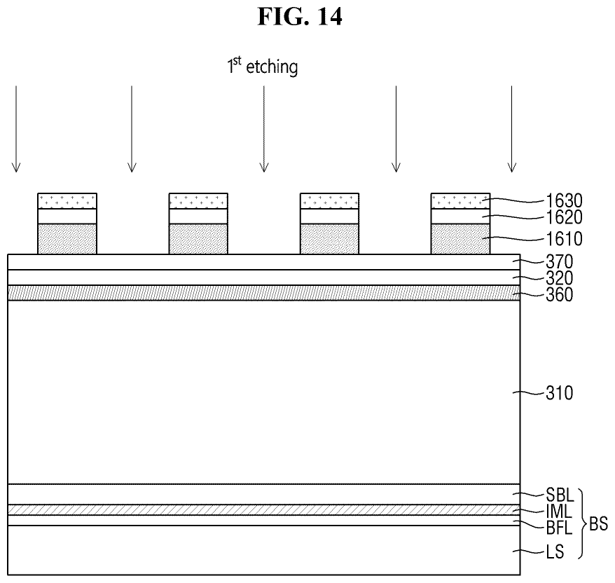

As shown in FIGS. 14 to 17, a first etching process (1^{st} etching) of etching the insulating mask layers 1610 and 1620 along the mask pattern 1630, and second and third etching processes (2^{nd} etching and 3^{rd} etching) of etching the semiconductor material layers 310 and 320 along the etched insulating mask layers 1610 and 1620 may be performed. Each etching process may be performed in a direction perpendicular to the top surface of the base substrate BS.

The etching process may be dry etching, wet etching, reactive ion etching (RIE), inductively coupled plasma reactive ion etching (ICP-RIE), or the like. The dry etching method may be suitable for vertical etching because anisotropic etching may be performed. In the case of using the aforementioned etching method, it may be possible to use Cl₂ or O₂ as an etchant. However, the disclosure is not limited thereto.

The first etching process (1^{st} etching) may be a process of etching the insulating mask layers 1610 and 1620 exposed in the regions between the mask patterns 1630 spaced apart from each other. The insulating mask layers 1610 and 1620 may be etched along the mask patterns 1630, and may function as a mask for etching the underlying semiconductor material layers.

The semiconductor material layers may be etched by using the mask patterns 1630 and the etched insulating mask layers 1610 and 1620 as a mask. The process of etching the semiconductor material layers may include the second etching process (2^{nd} etching) of a dry etching process, and the third etching process (3^{rd} etching) of a wet etching process performed after the second etching process (2^{nd} etching).

In the second etching process (2^{nd} etching), the semiconductor material layers may be etched in the direction perpendicular to the top surface of the base substrate BS to form semiconductor rods spaced apart from each other. However, in this etching process, the side surfaces of the semiconductor rods may have an inclined surface rather than being perpendicular to the top surface of the base substrate BS. The third etching process (3^{rd} etching) may be performed so that the side surfaces of the semiconductor rods may be perpendicular to the base substrate BS. The second etching process (2^{nd} etching) and the third etching process (3^{rd} etching) may be performed as a dry etching process and a wet etching process, respectively. Through these etching processes, the semiconductor rods spaced apart from each other may be formed on the base substrate BS. Each of the semiconductor rods may include the first semiconductor material layer 310, the active material layer 360, the second semiconductor material layer 320, and the electrode material layer 370.

However, as described above, the surfaces or side surfaces of the semiconductor rods formed through the etching process may be damaged. Due to such surface damage, abnormal recombination of the light emitting elements ED may occur in the semiconductor layer, and the luminous efficiency and the electrical characteristics of the light emitting elements ED may deteriorate. To minimize this performance degradation, the light emitting element ED may include the insulating film 38 surrounding at least the side surfaces of the semiconductor layers 31, 32, 36, and 37. For example, the light emitting element ED according to one embodiment may include the insulating film 38 formed through a sol-gel process.

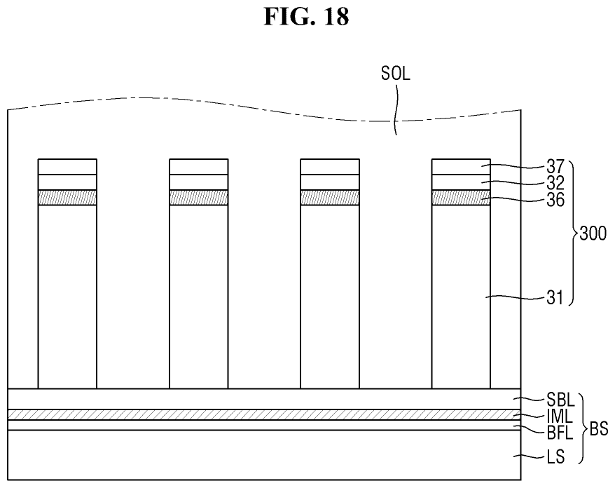

Referring to FIGS. 18 to 20, the insulating film 38 may be formed to partially surround the side surface of a semiconductor rod 300. The formation of the insulating film 38 may be carried out by performing a process of forming an insulating material layer 380 so as to surround the outer surface of the semiconductor rod 300 and partially removing the insulating material layer 380 to expose the top surface of the semiconductor rod 300.

The insulating film 38 may be an insulating layer formed on the outer surface of the semiconductor rod 300, and may be formed by immersing or applying an insulating material on the outer surface of the vertically etched semiconductor rod 300. According to one embodiment, the insulating film 38 and/or the insulating material layer 380 may be formed through a sol-gel process.

The sol-gel process may be include a process of immersing the semiconductor rods 300, or the semiconductor rod 300 and the base substrate BS in a solution SOL containing a precursor material of the material constituting the insulating film 38 and/or the insulating material layer 380, adding a reactant to the solution SOL, and agitating the solution SOL. The sol-gel process may require relatively less harsh process conditions as compared to other chemical processes, such as chemical vapor deposition (CVD) and atomic layer deposition (ALD). For example, the sol-gel process may be performed by immersing the semiconductor rods 300 in the solution SOL containing the precursor material and adding a reactant to the solution SOL to allow them to react at a low temperature.

In the drawing, although the insulating film 38 is shown as a single layer, the insulating film 38 may include the first insulating film 38A and the second insulating film 38B, each of which includes at least one layer, as stated above. Since the respective layers of the first insulating film 38A and the second insulating film 38B include different materials, the reaction may be repeated in different solutions SOL in the sol-gel process.

In some embodiments, the sol-gel process may include a process of immersing the semiconductor rods 300 in the solution SOL and agitating the solution SOL for about 15 minutes to about 80 minutes at a temperature of about 25° C. For example, the solution SOL may be agitated about 60 minutes at a temperature of about 25° C. Since the reaction of the sol-gel process is performed at a lower temperature compared to other deposition processes, less damage may be inflicted on the semiconductor rod. In particular, other deposition processes may include a high-temperature process or a plasma irradiation process in order to completely form the insulating material layer 380. Since, however, the sol-gel process does not involve these processes, formation of defects in the semiconductor rod may be minimized.

The reaction time of the sol-gel process may depend on the content of the reactant and the precursor material contained in the solution SOL, and the thickness of the insulating material layer 380 and/or the insulating film 38 formed on the semiconductor rods may also depend on the content of the reactant and the precursor material contained in the solution SOL. The reaction time of the sol-gel process may be long enough for all of the precursor material and the reactant in the solution SOL to react, and once all the precursor material has reacted, the thickness of the insulating material layer 380 and/or the insulating film 38 may no longer increase even if the process time of the sol-gel process increases. The process time of the sol-gel process may depend on the thickness of each layer of the first insulating film 38A and the second insulating film 38B.

The insulating material layer 380 formed through the sol-gel process may be formed on the side and top surfaces of the semiconductor rod 300 and on the base substrate BS exposed at regions between the semiconductor rods 300 spaced apart from each other. In order to partially remove the insulating material layer 380 disposed on the top surfaces of the semiconductor rods 300 and the regions between the semiconductor rods 300 spaced apart from each other, dry etching or etch-back, which is an anisotropic etching, may be performed. In some embodiments, the top surface of the insulating material layer 380 may be removed to expose the electrode material layer 370, and in this process, the electrode material layer 370 may also be partially etched. In the light emitting element ED, the thickness of the electrode layer 37 of the finally manufactured light emitting element ED may be smaller than the thickness of the electrode material layer 370 formed during the manufacturing process. After a portion of the insulating material layer 380 is removed, the insulating film 38 surrounding the side surfaces of the semiconductor layers in the light emitting element ED may be formed.

Although it is illustrated in the drawing that the top surface of the electrode layer 37 is exposed and the top surface of the insulating film 38 is flat, the disclosure is not limited thereto. In some embodiments, the insulating film 38 may be formed to have a partially curved top surface in a portion surrounding the electrode layer 37. In the process of partially removing the insulating material layer 380, not only the top surface of the insulating material layer 380 but also a portion of the side surface of the insulating material layer 380 may be removed, so that the end surface of the insulating film 38 surrounding the semiconductor layers may be partially etched. As the top surface of the insulating material layer 380 is removed, the outer surface of the insulating film 38 adjacent to the electrode layer 37 in the light emitting element ED may be partially removed.

Although not shown in the drawing, once the light emitting elements ED are formed after the sol-gel process is performed on the base substrate BS, a process of heat-treating the light emitting elements ED may be further performed. Through the heat-treatment process, the insulating films 38 of the light emitting elements ED may be put in a more stable state. The sol-gel process may be performed at a relatively low temperature. If the insulating film 38 formed in this way is heat-treated, the insulating film 38 of the light emitting element ED may be made more robust, and the optical properties of the light emitting element ED may be improved as will be described below. In an embodiment, the heat treatment process may be performed at a temperature range of about 200° C. to about 300° C. For example, the heat treatment process may be performed at a temperature of about 250° C. In an embodiment, the heat treatment process may be performed for about 30 minutes to about 2 hours. For example, the heat treatment process may be performed for about 1 hour. However, the disclosure is not limited thereto.

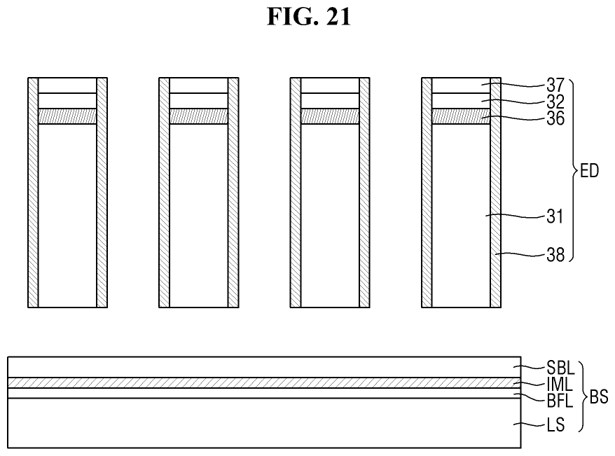

As shown in FIG. 21, the light emitting element ED on which the insulating film 38 is formed may be separated from the base substrate BS.

Through the above-described process, the light emitting element ED including the insulating film 38 formed through the sol-gel process and the locally aggregated indium (In) may be manufactured. Although the light emitting element ED may have defects on its surface as the etching process (2^{nd} etching and 3^{rd} etching) is performed to etch the semiconductor material layers, such defects may be reduced by the insulating film 38 formed through the sol-gel process. In an embodiment, in the process of forming the active layer 36, a region where the indium (In) is locally aggregated may be formed through a temperature control. Accordingly, surface defects of the light emitting element ED may be reduced or the number of the electrons trapped in the defects may be reduced, so that the rate of electrons recombined in the active layer 36 may be increased. The light emitting element ED may have high external quantum efficiency compared to its small diameter as it is manufactured through the above-described manufacturing method.

Hereinafter, a display device including the light emitting element ED according to one embodiment and electronic devices applied to the display device will be described.

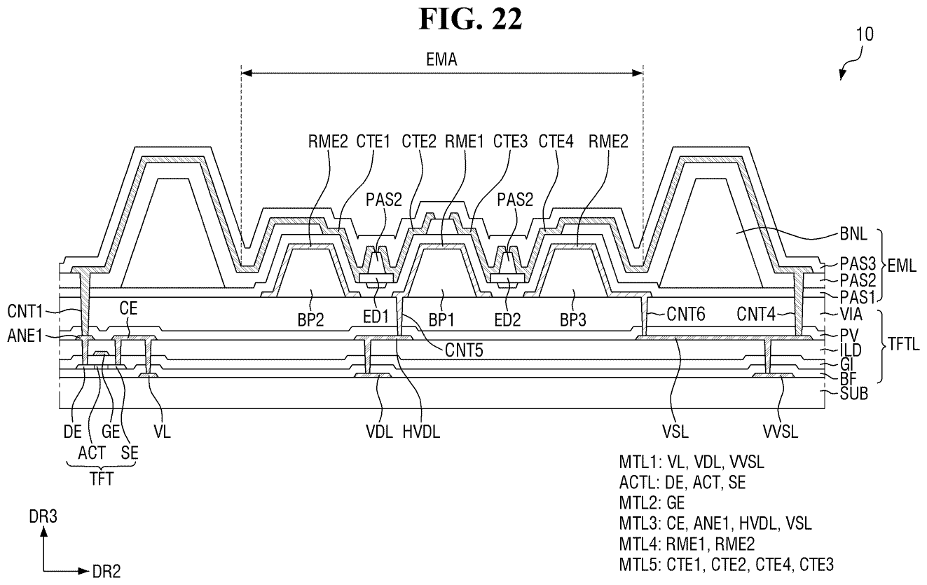

FIG. 22 is a schematic cross-sectional view of a display device according to one embodiment.

Referring to FIG. 22, the display device 10 according to one embodiment may include a substrate SU B, a thin film transistor layer TFTL, and a light emitting element layer EML. The display device 10 may include the light emitting element ED disposed in the light emitting element layer EML and thus emit light.

The substrate SUB may be a base substrate or a base member. The substrate SUB may be a flexible substrate which can be bent, folded or rolled. For example, the substrate SUB may include a glass material or a metal material, but the disclosure is not limited thereto. In another embodiment, the substrate SUB may include a polymer resin including polyimide (PI).

The thin film transistor layer TFTL may be disposed on the substrate SUB. The thin film transistor layer TFTL may include a first metal layer MTL1, a buffer layer BF, an active layer ACTL, a gate insulating layer GI, a second metal layer MTL2, an interlayer insulating layer IL D, a third metal layer MTL3, a passivation layer PV, and a via layer VIA.

The first metal layer MTL1 may be disposed on the substrate SUB. The first metal layer MTL1 may include a voltage line VL, a first voltage line VDL, and a vertical voltage line VVSL. The voltage line VL may be the first voltage line VDL, an initialization voltage line, or a data line.

The buffer layer BF may be disposed on the first metal layer MTL1. For example, the buffer layer BF may include an inorganic film capable of preventing permeation of air or moisture. For example, the buffer layer BF may include multiple inorganic films laminated alternately.

The active layer ACTL may be disposed on the buffer layer BF. The active layer ACTL may include a drain electrode DE, a semiconductor region ACT, and a source electrode SE of a thin film transistor TFT. For example, the semiconductor region ACT of the thin film transistor TFT may include low temperature polycrystalline silicon (LTPS). The thin film transistor TFT containing a low-temperature polycrystalline silicon may have high electron mobility and excellent turn-on characteristics. In another embodiment, the semiconductor region ACT of the thin film transistor TFT may include an oxide semiconductor. The thin film transistor TFT containing an oxide semiconductor may have excellent leakage current characteristics and be driven at a low frequency, so that power consumption may be reduced.

The gate insulating layer GI may be disposed on the active layer ACTL. The gate insulating layer GI may insulate the active layer A CTL from the second metal layer MTL2.

The second metal layer MTL2 may be disposed on the gate insulating layer GI. The second metal layer MTL2 may include the gate electrode GE of the thin film transistor TFT. The gate electrode GE of the thin film transistor TFT may overlap the semiconductor region ACT in a thickness direction of the substrate SUB.

The interlayer insulating layer ILD may be disposed on the second metal layer MTL2. The interlayer insulating layer ILD may insulate the second metal layer MTL2 from the third metal layer MTL3.

The third metal layer MTL3 may be disposed on the interlayer insulating layer ILD. The third metal layer MTL3 may include a connection electrode CE, a first anode connection electrode ANE1, a horizontal voltage line HVDL, and a second voltage line VSL. The connection electrode CE may electrically connect the voltage line VL to the source electrode SE of the thin film transistor TFT. The first anode connection electrode ANE1 may electrically connect the drain electrode DE of the thin film transistor TFT to a first contact electrode CTE1. The horizontal voltage line HVDL may electrically connect the first voltage line VDL to a first electrode RME1. The second voltage line VSL may electrically connect the vertical voltage line VVSL to a second electrode RME2, and may electrically connect the vertical voltage line VVSL to a fifth contact electrode CTE5.

The passivation layer PV may be disposed on the third metal layer MTL3. The passivation layer PV may be disposed above the thin film transistors TFT to protect pixel circuits of pixels.

The via layer VIA may be disposed on the passivation layer PV. The via layer VIA may planarize the top of the thin film transistor layer TFTL. The via layer VIA may contain an organic insulating material such as polyimide (PI).

The light emitting element layer EML may be disposed on the thin film transistor layer TFTL. The light emitting element layer EML may include first to third bank patterns BP1, BP2, and BP3, the first and second electrodes RME1 and RME2, a first insulating layer PAS1, light emitting elements ED1 and ED2, a bank layer BNL, a second insulating layer PAS2, first to fourth contact electrodes CTE1, CTE2, CTE3, and CTE4, and a third insulating layer PAS3.

The bank layer BNL may define an emission area EMA. The bank layer BNL may surround an area where the light emitting element ED1 and ED2 and the electrodes RME1 and RME2 are disposed in a plan view.

The first to third bank patterns BP1, BP2, and BP3 may be spaced apart from each other in a horizontal direction. The first bank pattern BP1 may be disposed between the second and third bank patterns BP2 and BP3. The second bank pattern BP2 may be disposed on the left side of the first bank pattern BP1, and the third bank pattern BP3 may be disposed on the right side of the first bank pattern BP1. Each of the first to third bank patterns BP1, BP2, and BP3 may protrude in an upward direction (a thickness direction) on a via layer VIA. Each of the first to third bank patterns BP1, BP2, and BP3 may have an inclined side surface. The light emitting elements ED1 and ED2 may be disposed between the bank patterns BP1, BP2, and BP3 that are spaced apart from each other. For example, the first light emitting element ED1 may be disposed between the first bank pattern BP1 and the second bank pattern BP2, and the second light emitting element ED2 may be disposed between the first bank pattern BP1 and the third bank pattern BP3.

The first electrode RME1 and the second electrode RME2 may be disposed in a fourth metal layer MTL4. The maximum width of the second electrode RME2 in a second direction DR2 may be greater than the maximum width of the first electrode RME1 in the second direction DR2, but the disclosure is not limited thereto. The fourth metal layer MTL4 may be disposed on the via layer VIA and the first to third bank patterns BP1, BP2, and BP3.

The first electrode RME1 and the second electrode RME2 may cover the top surface and the inclined side surface of one of the first to third bank patterns BP1, BP2, and BP3. The first electrode RME1 and the second electrode RME2 may be reflective electrodes. The fourth metal layer MTL4 may be formed as a single layer or multiple layers including at least one of molybdenum (Mo), aluminum (Al), chromium (Cr), gold (Au), silver (Ag), titanium (Ti), nickel (Ni), palladium (Pd), indium (In), neodymium (Nd), and copper (Cu). The fourth metal layer MTL4 may include at least one layer containing a material having high reflectivity. Accordingly, each of the first electrode RME1 and the second electrode RME2 may reflect the light emitted from the light emitting elements ED1 and ED2 to the upward direction.

The first electrode RME1 may be connected to the horizontal voltage line HVDL of the third metal layer MTL3 through multiple fifth through holes CNT5. The first electrode RME1 may receive a driving voltage or a high-potential voltage from the horizontal voltage line HVDL. The second electrode RME2 may be connected to the second voltage line VSL of the third metal layer MTL3 through multiple sixth through holes CNT6. The second electrode RME2 may receive a low-potential voltage from the second voltage line VSL.

The first insulating layer PAS1 may cover the first and second electrodes RME1 and RME2. The first insulating layer PAS1 may include an inorganic film. The first and second light emitting elements ED1 and ED2 may be insulated from the first and second electrodes RME1 and RME2 by the first insulating layer PAS1. The light emitting elements ED1 and ED2 may be disposed on the first electrode RME1 and the second electrode RME2.

The first to fourth contact electrodes CTE1, CTE2, CTE3, and CTE4 may be disposed in a fifth metal layer MTL5. The first to fourth contact electrodes CTE1, CTE2, CTE3, and CTE4 may be transparent electrodes. For example, the fifth metal layer MTL5 may include a material such as indium tin oxide (ITO), indium zinc oxide (IZO), and indium tin zinc oxide (ITZO). The fifth metal layer MTL5 may have a stacked structure of ITO/Ag/ITO, ITO/A g/IZO, ITO/A g/ITZO/IZO, or the like, but the disclosure is not limited thereto.

The second insulating layer PAS2 may be disposed on the bank layer BNL, the first insulating layer PAS1, and the light emitting element ED. The third insulating layer PAS3 may cover the second insulating layer PAS2 and the first to fourth contact electrodes CTE1, CTE2, CTE3, and CTE4. The second and third insulating layers PAS2 and PAS3 may include an inorganic film. The second and third insulating layers PAS2 and PAS3 may insulate each of the first to fourth contact electrodes CTE1, CTE2, CTE3, and CTE4. Each of the second to fourth contact electrodes CTE2, CTE3, and CTE4 may include a void in the center, but the disclosure is not limited thereto.

The first contact electrode CTE1 may be disposed above the second electrode RME2, and may be connected to the first anode connection electrode ANE1 of the third metal layer MTL3 through a first through hole CNT1. The first contact electrode CTE1 may be connected between the first anode connection electrode ANE1 and ends of the first light emitting elements ED1. The first contact electrode CTE1 may supply a driving current to the first light emitting element ED1. The first contact electrode CTE1 may correspond to an anode electrode of the first light emitting elements ED1, but the disclosure is not limited thereto.

The second contact electrode CTE2 may be disposed above the first electrode RME1. The second contact electrode CTE2 may be connected to another ends of the first light emitting elements ED1. The second contact electrode CTE2 may correspond to a cathode electrode of the first light emitting elements ED1, but the disclosure is not limited thereto.

The third contact electrode CTE3 may be disposed above the first electrode RME1. The third contact electrode CTE3 may be connected to end of the second light emitting element ED2. The third contact electrode CTE3 may correspond to the anode electrode of the second light emitting element ED2, but the disclosure is not limited thereto.

The fourth contact electrode CTE4 may be disposed above the second electrode RME2, and may be connected to the second voltage line VSL of the third metal layer MTL3 through a fourth through hole CNT4. The fourth contact electrode CTE4 may be connected between the second voltage line VSL and another end of the second light emitting element ED2. The fourth contact electrode CTE4 may correspond to a cathode electrode of the second light emitting elements ED2, but the disclosure is not limited thereto. The fourth contact electrode CTE4 may receive a low potential voltage through the second voltage line VSL.

In the display device 10 of FIG. 22, the two electrodes RME1 and RME2 spaced apart in parallel may be disposed above the substrate SU B, and the light emitting element ED may be disposed in a direction parallel to the top surface of the substrate SUB. However, the disclosure is not limited thereto. Depending on the structure of the display device 10, the light emitting element ED may be disposed in a direction perpendicular to the top surface of the substrate SUB.

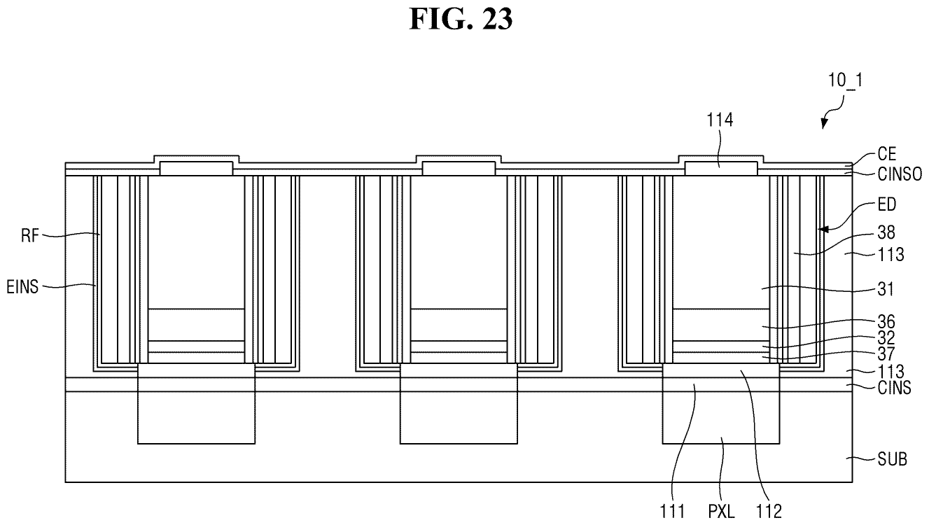

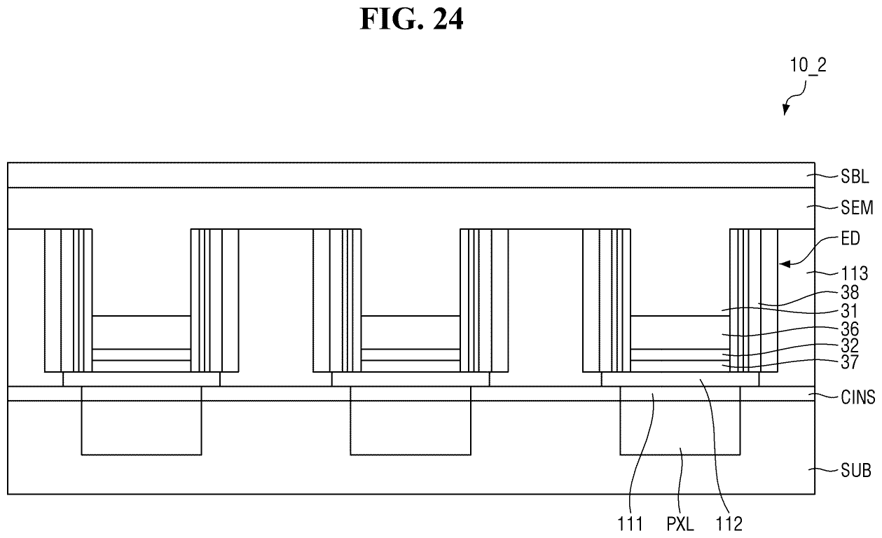

FIGS. 23 and 24 are schematic cross-sectional views of a display device according to another embodiment.

Referring to FIG. 23, a display device 10_1 may include, above the substrate SUB, the light emitting elements ED spaced apart from each other. The light emitting elements ED may be disposed so that the direction in which the semiconductor layers 31 and 32 are stacked is perpendicular to the top surface of the substrate SU B.

The display device 10_1 may include the substrate SUB, multiple pixel circuit units PXL formed on the substrate SUB, and the light emitting elements ED disposed above the substrate SUB.

The substrate SUB may be a silicon wafer substrate formed using a semiconductor process. The pixel circuit units PXL of the substrate SUB may be formed by using a semiconductor process.

The pixel circuit units PXL may be disposed on the entire surface of the display device 10_1. Each of the pixel circuit units PXL may be connected to the corresponding pixel electrode 111. For example, the pixel circuit units PXL and the pixel electrodes 111 may be connected in a one-to-one correspondence. Each of the pixel circuit units PXL may overlap the light emitting element ED in a thickness direction.

Each of the pixel circuit units PXL may include at least one transistor formed by a semiconductor process. Further, each of the pixel circuit units PX L may further include at least one capacitor formed by a semiconductor process. The pixel circuit units PXL may include, for example, a CMOS circuit. Each of the pixel circuit units PXL may apply a pixel voltage or an anode voltage to the pixel electrode 111.

The circuit insulating layer CINS may be disposed on the substrate SUB. The circuit insulation layer CINS may expose each of the pixel electrodes 111 so that each pixel electrode 111 may be connected to the light emitting element ED. The circuit insulation layer CINS may protect the pixel circuit units PXL, and may flatten the steps formed by the pixel electrodes 111 disposed on the pixel circuit units PXL. The circuit insulating layer CINS may include an inorganic insulating material such as silicon oxide (SiOₓ), silicon nitride (SiNₓ), silicon oxynitride (SiOₓN_{y}), aluminum oxide (AlₓO_{y}), and aluminum nitride (AlN).

Each of the pixel electrodes 111 may be disposed on a corresponding pixel circuit unit PXL. Each of the pixel electrodes 111 may be an exposed electrode exposed from the pixel circuit unit PXL. Each of the pixel electrodes 111 may be integrally formed with a corresponding pixel circuit unit PXL. Each of the pixel electrodes 111 may be supplied with a pixel voltage or an anode voltage from the pixel circuit unit PXL. The pixel electrodes 111 may include a metal material such as aluminum (AI).

The light emitting element layer may be disposed on the substrate SUB. The light emitting element layer may include connection electrodes 112 and 114, the light emitting element ED, and a common electrode CE. In an embodiment, the light emitting element layer may include a reflective layer RF and a planarization layer 113.

The first connection electrodes 112 may be disposed on the corresponding pixel electrodes 111. The first connection electrodes 112 may include a metal material for electrically connecting the pixel electrodes 111 to the light emitting elements ED. For example, the first connection electrodes 112 may include at least one of gold (Au), copper (Cu), aluminum (Al), and tin (Sn). In another embodiment, the first connection electrodes 112 may include a first layer including one of gold (Au), copper (Cu), aluminum (Al), and tin (Sn) and a second layer including another one of gold (Au), copper (Cu), aluminum (AI), and tin (Sn).

The light emitting element ED may be disposed on the first connection electrode 112. The light emitting element ED may be the light emitting element ED described above with reference to FIG. 1. The display device 10_1 may include the light emitting elements ED disposed respectively correspond to the pixel electrodes 111 and first connection electrodes 112. The light emitting elements ED may have a shape extending in a direction, and may be disposed such that the direction is perpendicular to the top surface of the substrate SUB. In an embodiment, the light emitting element ED may be disposed such that the second semiconductor layer 32 or the electrode layer 37 faces the first connection electrode 112.

The reflective layer RF and an element insulating layer EINS may be disposed on the lateral side of the light emitting element ED.

The reflective layer RF may surround the insulating film 38 of the light emitting element ED. The reflective layer RF may reflect the light emitted from the lateral side of the light emitting element ED to the upward direction. In an embodiment, the reflective layer RF may include a material having high reflectivity. For example, the reflective layer RF may have a reflectance greater than or equal to about 90% within a visible range, and may have a thickness greater than or equal to about 5 nm.

The element insulating layer EINS, which is an insulating layer for protecting the reflective layer RF, may be disposed on the reflective layer RF. The element insulating layer EINS may be formed of aluminum oxide (Al₂O₃), but the disclosure is not limited thereto.

The planarization layer 113 may disposed on the circuit insulation layer CINS and surround the light emitting elements ED. The planarization layer 113 may be a layer for flattening the step formed by each light emitting element ED. The planarization layer 113 may be formed of an organic film including an acryl resin, an epoxy resin, a phenolic resin, a polyamide resin, a polyimide resin, or the like.

An element insulating layer CINSO may be disposed on the planarization layer 113 and the light emitting element ED. The element insulating layer CINSO may expose each of the light emitting elements ED so that each light emitting element ED may be connected to the common electrode CE. The element insulating layer CINSO may protect the light emitting elements ED. The element insulating layer CINSO may include multiple openings overlapping the light emitting elements ED in a plan view, and a portion of the bottom surface of the first semiconductor layer 31 of each light emitting element ED may be exposed.

The second connection electrodes 114 may be disposed on the light emitting elements ED. The second connection electrodes 114 may include a metal material for electrically connecting the common electrode CE described below to the light emitting elements ED. For example, the second connection electrodes 114 may include at least one of gold (Au), copper (Cu), aluminum (Al), and tin (Sn). In another embodiment, the second connection electrodes 114 may include a first layer including one of gold (Au), copper (Cu), aluminum (Al), and tin (Sn) and a second layer including another one of gold (Au), copper (Cu), aluminum (AI), and tin (Sn).

The common electrode CE may be disposed on the second connection electrode 114 and the planarization layer 113. The common electrode CE may be a common layer formed commonly over the pixels. The common electrode CE may be made of a transparent conductive material (TCO) such as indium tin oxide (ITO) and indium zinc oxide (IZO) capable of transmitting light.

[001.78] Referring to FIG. 24, a display device 10_2 may include the light emitting elements ED disposed above the substrate SUB in a vertical direction, and the first semiconductor layers 31 of the light emitting elements ED may be connected to each other. In the display device 10_2 according to an embodiment, the first semiconductor material layer 310 may not be completely etched and its lower portion may partially remain during the manufacturing process of the light-emitting element ED, and the light emitting elements ED may be connected to each other through a common semiconductor layer SEM in which the first semiconductor material layer 310 is not completely etched. Further, the display device 10_2 may include the semiconductor base layer SBL disposed on the common semiconductor layer SEM. The semiconductor base layer SBL may be a layer disposed on the intermediate layer IML of the base substrate BS during the manufacturing process of the light emitting element ED. The light emitting elements ED may be disposed above the substrate SUB and not individually separated but integrated with each other on the semiconductor base layer SBL to thereby constitute the display device 10_2. The embodiment of FIG. 24 is different from the embodiment of FIG. 23 in that the light emitting elements ED are connected to each other and the common electrode CE is omitted.

The common semiconductor layer SEM and the first semiconductor layer 31 may include substantially a same material. The individual light emitting elements ED may have a shape that protrudes from the common semiconductor layer SEM, and the insulating film 38 may surround the semiconductor layers 31 and 32 and the active layer 36 that are protruded from the common semiconductor layer SEM. In the manufacturing process of the light emitting element ED, as the intermediate layer IML is disposed below the semiconductor base layer SBL, the semiconductor base layer SBL may have a low defect density. As described above, the defect density of the semiconductor base layer SBL may be less than or equal to about 1.0*10⁸/cm². For example, the defect density of the semiconductor base layer SBL may be less than or equal to about 6*10⁷/cm². The common semiconductor layer SEM serving as a common electrode of the light emitting elements ED in the display device 10_2 may also have a low defect density. The light emitting elements ED may be disposed above the substrate SUB while being connected with each other by the common semiconductor layer SEM and the semiconductor base layer SBL of the base substrate BS without being individually separated during the manufacturing process, to thereby constitute the display device 10_2.

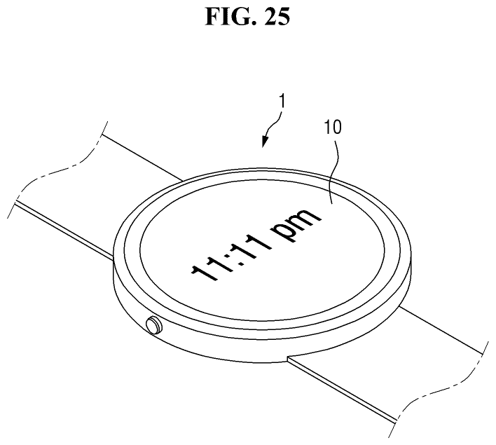

FIGS. 25 to 30 are schematic diagrams showing electronic devices including a display device according to one embodiment.

Referring to FIG. 25, the display device 10 according to one embodiment may be applied to a smart watch 1. FIG. 25 schematically illustrates that the smart watch 1 has a circular shape in a plan view, except for its wrist watch strap. The smart watch 1 may include the display device 10 having a circular shape, so is the smart watch 1 may be designed to conform to the planar shape of the display device 10.

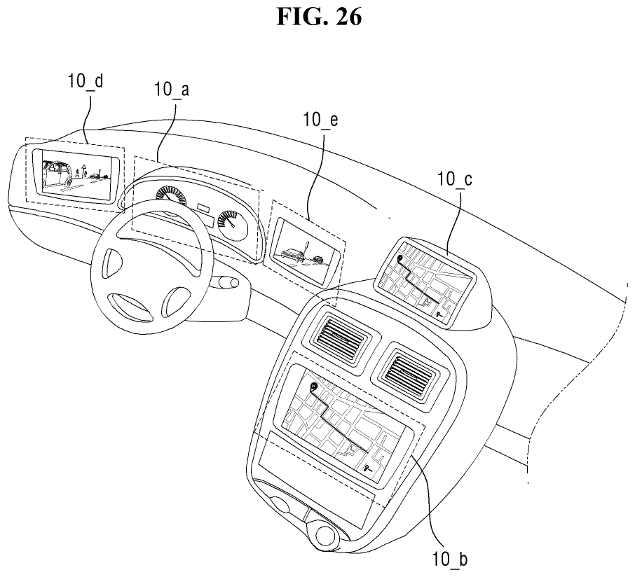

Referring to FIG. 26, display devices 10_a, 10_b, 10_c, 10_d, and 10_e according to one embodiment may be applied to a dashboard of an automobile, a center fascia of the automobile, or a center information display (CID) of the dashboard of the automobile. Further, the display devices according to one embodiment may be applied to a room mirror display instead of side mirrors of the automobile.

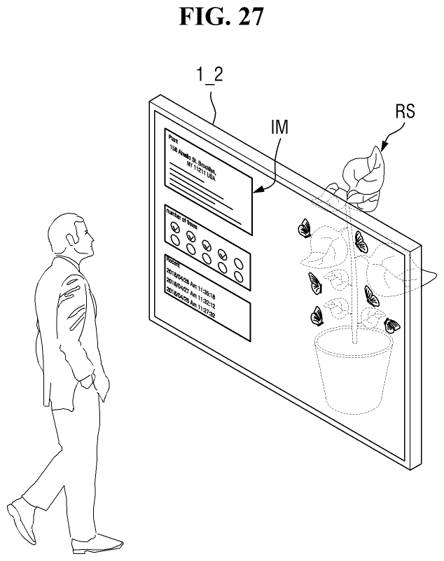

Referring to FIG. 27, the display device according to one embodiment may be applied to a transparent display device 1_2. The transparent display device may display an image IM, and also may transmit light. Thus, a user located on the front side of the transparent display device 1_2 may view an object RS or a background on the rear side of the transparent display device 1_2 as well as the image IM displayed on the transparent display device 1_2. In case that the display device is applied to the transparent display device 1_2, the substrate of the display device may include a light transmitting portion capable of transmitting light or may be made of a material capable of transmitting light.

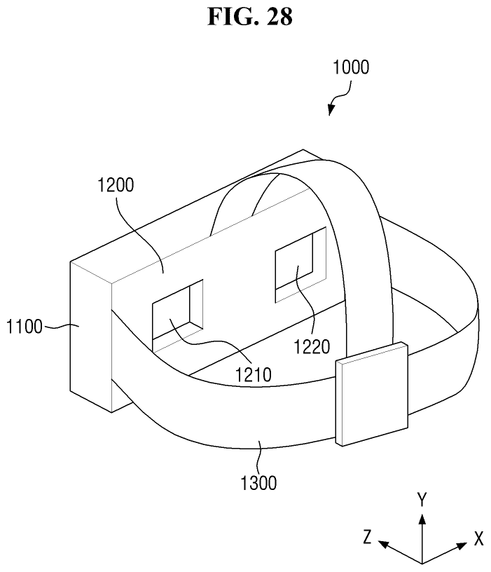

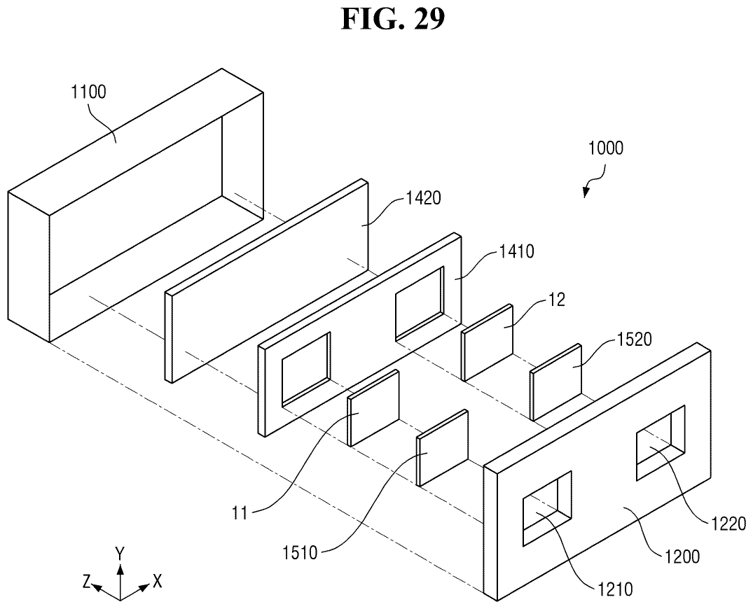

Referring to FIGS. 28 and 29, a head mounted display device 1000 according to one embodiment may include a first display device 11, a second display device 12, a display device housing 1100, a housing cover 1200, a first eyepiece 1210, a second eyepiece 1220, a head mounted band 1300, a middle frame 1410, a first optical member 1510, a second optical member 1520, a control circuit board 1420, and a connector.

The first display device 11 may provide an image to a user's left eye, and the second display device 12 may provide an image to a user's right eye. Since each of the first display device 11 and the second display device 12 is substantially the same as the display device 10 described above, the description of the first display device 11 and the second display device 12 will be omitted.

The first optical member 1510 may be disposed between the first display device 11 and the first eyepiece 1210. The second optical member 1520 may be disposed between the second display device 12 and the second eyepiece 1220. Each of the first optical member 1510 and the second optical member 1520 may include at least one convex lens.

The middle frame 1410 may be disposed between the first display device 11 and the control circuit board 1420 and between the second display device 12 and the control circuit board 1420. The middle frame 1410 may serve to support and fix the first display device 11, the second display device 12, and the control circuit board 1420.

The control circuit board 1420 may be disposed between the middle frame 1410 and the display device housing 1100. The control circuit board 1420 may be connected to the first display device 11 and the second display device 12 through the connector. The control circuit board 1420 may convert an image source input from the outside into digital video data, and may transmit the digital video data to the first display device 11 and the second display device 12 through the connector.

The control circuit board 1420 may transmit the digital video data corresponding to a left-eye image optimized for the user's left eye to the first display device 11, and may transmit the digital video data corresponding to a right-eye image optimized for the user's right eye to the second display device 12. In another embodiment, the control circuit board 1420 may transmit a same digital video data to the first display device 11 and the second display device 12.

The display device housing 1100 may serve to accommodate the first display device 11, the second display device 12, the middle frame 1410, the first optical member 1510, the second optical member 1520, the control circuit board 1420, and the connector. The housing cover 1200 may cover an open surface of the display device housing 1100. The housing cover 1200 may include the first eyepiece 1210 at which the user's left eye is located and the second eyepiece 1220 at which the user's right eye is located. It is illustrated in the drawing that the first eyepiece 1210 and the second eyepiece 1220 are disposed separately, but the disclosure is not limited thereto. The first eyepiece 1210 and the second eyepiece 1220 may be combined into one.

The first eyepiece 1210 may be aligned with the first display device 11 and the first optical member 1510, and the second eyepiece 1220 may be aligned with the second display device 12 and the second optical member 1520. Accordingly, the user may view the image of the first display device 11 magnified as a virtual image by the first optical member 1510 through the first eyepiece 1210, and may view the image of the second display device 12 magnified as a virtual image by the second optical member 1520 through the second eyepiece 1220.

The head mounted band 1300 may serve to secure the display device housing 1100 to the user's head such that the first eyepiece 1210 and the second eyepiece 1220 of the housing cover 1200 remain located on the user's left and right eyes, respectively. In case that the display device housing 1200 is implemented to be lightweight and compact, the head mounted display device 1000 may be provided with an eyeglass frame instead of the head mounted band 1300.

In an embodiment, the head mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

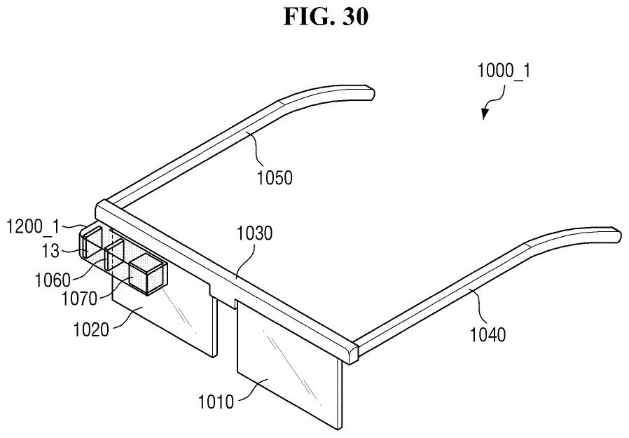

Referring to FIG. 30, a head mounted display device 1000_1 according to one embodiment may be an eyeglasses-type display device in which a display device housing 1200_1 is implemented in a lightweight and compact manner. The head mounted display device 1000_1 according to one embodiment may include a display device 13, a left eye lens 1010, a right eye lens 1020, a support frame 1030, temples 1040 and 1050, an optical member 1060, an optical path changing member 1070, and the display device housing 1200_1.

The display device housing 1200_1 may house the display device 13, the optical member 1060, and the optical path changing member 1070. An image displayed on the display device 13 may be magnified by the optical member 1060, and the optical path may be changed by the optical path changing member 1070 to provide the image to the user's right eye through the right eye lens 1020. As a result, the user may view an augmented reality image, through the right eye, in which a virtual image displayed on the display device 13 and a real image seen through the right eye lens 1020 are combined.

It is illustrated in the drawing that the display device housing 1200_1 is disposed at the right end of the support frame 1030, but the disclosure is not limited thereto. For example, the display device housing 1200_1 may be disposed on the left end of the support frame 1030, and the image of the display device 13 may be provided to the user's left eye. In another embodiment, the display device housing 1200_1 may be disposed on both the left and right ends of the support frame 1030, and the user may view the image displayed on the display device 13 through both the left and right eyes.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light emitting element comprising:
a first semiconductor layer doped with an n-type dopant;
a second semiconductor layer disposed on the first semiconductor layer and doped with a p-type dopant;
an active layer disposed between the first semiconductor layer and the second semiconductor layer;
an electrode layer disposed on the second semiconductor layer; and
an insulating film surrounding at least a side surface of the active layer, wherein
the first semiconductor layer has a diameter in a range of about 0.5 μm to about 10 μm, and
the light emitting element has an external quantum efficiency greater than or equal to about 23%.

2. The light emitting element of claim 1, wherein
the first semiconductor layer has the diameter in a range of about 0.5 μm to about 1 μm, and
the light emitting element has the external quantum efficiency in a range of about 23% to about 23.3%.

3. The light emitting element of claim 1, wherein
the first semiconductor layer has the diameter in a range of about 1 μm to about 3 μm, and
the light emitting element has the external quantum efficiency in a range of about 23.3% to about 24.2%.

4. The light emitting element of claim 1, wherein
the first semiconductor layer has the diameter in a range of about 3 μm to about 5 μm, and
the light emitting element has the external quantum efficiency in a range of about 24.2% to about 25%.

5. The light emitting element of claim 1, wherein
the first semiconductor layer has the diameter in a range of about 5 μm to about 10 μm, and
the light emitting element has the external quantum efficiency in a range of about 25% to about 26%.

6. The light emitting element of claim 1, wherein
the insulating film comprises a first insulating film covering side surfaces of the first semiconductor layer, the second semiconductor layer, and the side surface of the active layer, and a second insulating film surrounding the first insulating film, and
a thickness of the second insulating film is greater than a thickness of the first insulating film in a radial direction of the active layer.

7. The light emitting element of claim 6, wherein
the first insulating film comprises a first layer, a second layer surrounding the first layer, and a third layer surrounding the second layer,
the first layer and the third layer include a same material, and
a thickness of the first layer is greater than a thickness of the second layer and a thickness of the third layer in the radial direction.

8. The light emitting element of claim 7, wherein
the first layer and the third layer include zirconium oxide (ZrO₂), and
the second layer includes aluminum oxide (Al₂O₃) or hafnium oxide (HfO₂).

9. The light emitting element of claim 7, wherein
the thickness of the first layer is about 2 nm, and
each of the thickness of the second layer and the thickness of the third layer is about 1 nm.

10. The light emitting element of claim 6, wherein
the second insulating film comprises a fourth layer and a fifth layer surrounding the fourth layer, and
a thickness of the fifth layer is greater than a thickness of the fourth layer in the radial direction.

11. The light emitting element of claim 10, wherein
each of the fourth layer and the fifth layer includes one of silicon oxide (SiOₓ), silicon nitride (SiNₓ), silicon oxynitride (SiOₓN_{y}), aluminum nitride (AlNₓ), aluminum oxide (Al₂O₃), zirconium oxide (ZrOₓ), hafnium oxide (HfOₓ), and titanium oxide (TiOₓ),
x is a rational number, and
y is another rational number.

12. The light emitting element of claim 10, wherein
the thickness of the fourth layer is greater than or equal to about 10 nm, and
the thickness of the fifth layer is in a range of about 40 nm to about 100 nm.

13. The light emitting element of claim 1, wherein
the active layer comprises a plurality of well layers and a plurality of barrier layers alternately stacked with each other, and
each of the plurality of well layers includes indium (In) and comprises a region where the indium is locally aggregated.

14. The light emitting element of claim 13, wherein each of the plurality of well layers of the active layer has a non-uniform density of an indium per unit area along a longitudinal direction of the active layer.

15. The light emitting element of claim 13, wherein each of the plurality of well layers of the active layer has a non-uniform density of an indium per unit area along a radial direction of the active layer.

16. A display device comprising:
a first electrode and a second electrode spaced apart from each other above a substrate; and
a light emitting element electrically connected to each of the first electrode and the second electrode, and having a shape extending in a direction, wherein
the light emitting element comprises:
a first semiconductor layer doped with an n-type dopant;
a second semiconductor layer disposed on the first semiconductor layer and doped with a p-type dopant;
an active layer disposed between the first semiconductor layer and the second semiconductor layer;
an electrode layer disposed on the second semiconductor layer; and
an insulating film surrounding at least a side surface of the active layer,
the first semiconductor layer has a diameter in a range of about 0.5 μm to about 10 μm, and
the light emitting element has an external quantum efficiency greater than or equal to about 23%.

17. The display device of claim 16, wherein
the insulating film of the light emitting element comprises a first layer covering side surfaces of the first semiconductor layer, the second semiconductor layer, and the side surface of the active layer, a second layer surrounding the first layer, a third layer surrounding the second layer, a fourth layer covering the third layer, and a fifth layer surrounding the fourth layer,
the first layer and the third layer include a same material,
a thickness of the first layer is greater than a thickness of the second layer and a thickness of the third layer in a radial direction of the active layer, and
a thickness of the fifth layer is greater than a thickness of the fourth layer in the radial direction.

18. The display device of claim 17, wherein
the first layer and the third layer include zirconium oxide (ZrO 2),
the second layer includes aluminum oxide (Al₂O₃) or hafnium oxide (HfO₂),
each of the fourth layer and the fifth layer include one of silicon oxide (SiOₓ), silicon nitride (SiNₓ), silicon oxynitride (SiOₓN_{y}), aluminum nitride (AlNₓ), aluminum oxide (Al₂O₃), zirconium oxide (ZrOₓ), hafnium oxide (HfOₓ), and titanium oxide (TiOₓ),
x is a rational number, and
y is another rational number.

19. The display device of claim 17, wherein
the thickness of the first layer is about 2 nm,
each of the thickness of the second layer and the thickness of the third layer is about 1 nm,
the thickness of the fourth layer is greater than or equal to about 10 nm, and
the thickness of the fifth layer is in a range of about 40 nm to about 100 nm.

20. The display device of claim 16, wherein
the active layer of the light emitting element comprises a plurality of well layers and a plurality of barrier layers alternately stacked with each other,
each of the plurality of well layers includes indium (In) and comprises a region where the indium is locally aggregated, and
each of the plurality of well layers of the active layer has a non-uniform density of an indium per unit area along a longitudinal direction and a radial direction of the active layer.
